(19) United States
(12) Patent Application Publication
(10) Pub. No.: US 2026/0293594 A1
(43) Pub. Date: Sep. 24, 2026

(54) CONVEYANCE APPARATUS, LASER IRRADIATION APPARATUS, CONVEYANCE METHOD, AND METHOD FOR MANUFACTURING SEMICONDUCTOR DEVICE

(71) Applicant: JSW Aktina System Co., Ltd., Yokohama-shi, Kanagawa (JP)

(72) Inventors: Ryo SHIMIZU, Yokohama-shi, Kanagawa (JP); Takahiro FUJI, Yokohama-shi, Kanagawa (JP); Yoshihiro YAMAGUCHI, Yokohama-shi, Kanagawa (JP); Tamotsu ODAJIMA, Yokohama-shi, Kanagawa (JP)

(73) Assignee: JSW Aktina System Co., Ltd., Yokohama-shi, Kanagawa (JP)

(21) Appl. No.: 19/473,541

(22) PCT Filed: Apr. 12, 2023
(86) PCT No.: PCT/JP2023/014881

§ 371 Date: Oct. 8, 2025

(51) Int. Cl. H10P 72/30; B23K 26/08; B23K 26/352; B65G 49/06; H10P 14/20

(52) U.S. Cl. CPC H10P 72/3208; B23K 26/0823; B23K 26/0838; B23K 26/352; B65G 49/065; H10P 14/381

(57) ABSTRACT

A conveyance apparatus according to an embodiment is configured to convey a substrate, and includes: a main levitation unit including an irradiation area disposed directly below an irradiation place of the laser light, and configured to levitate the substrate; a first rotation mechanism configured to rotate the substrate; a first conveyance mechanism configured to convey the substrate in a first direction in a state in which the angle of the edge of the substrate is the first angle; and a second conveyance mechanism configured to convey, in order to change an irradiation place of the laser light on the substrate, the substrate conveyed by the first conveyance mechanism in a second direction in the state in which the angle of the edge of the substrate is the first angle.

### TECHNICAL FIELD

The present disclosure relates to a conveyance apparatus, a laser irradiation apparatus, a conveyance method, and a method for manufacturing a semiconductor device.

### BACKGROUND ART

Patent Literature 1 discloses a laser annealing apparatus for forming a polycrystalline silicon thin film. In Patent Literature 1, a projection lens concentrates laser light over a substrate so that the laser light forms a linear irradiation area. As a result, an amorphous silicon film is crystallized and becomes a polysilicon film.

In Patent Literature 1, a conveyance unit conveys the substrate while a levitation unit levitates the substrate. Further, the substrate is carried into the levitation unit and carried out therefrom at the same place in the levitation unit. The conveyance unit conveys the substrate along each of the sides of the levitation unit. Further, the substrate is conveyed in a circulating manner twice over the levitation unit, so that substantially the entire surface of the substrate is irradiated with laser light.

### CITATION LIST

### Patent Literature

Patent Literature 1: Japanese Unexamined Patent Application Publication No. 2018-64048

### SUMMARY OF INVENTION

In such a conveyance apparatus for a laser irradiation apparatus, it is desired to appropriately convey a substrate so that a laser irradiation process is performed at a high speed and in a stable manner.

Other problems to be solved and novel features will become apparent from descriptions in this specification and accompanying drawings.

According to an embodiment, a conveyance apparatus is configured to convey a substrate in order to irradiate the substrate with line-shaped laser light, and includes: a main levitation unit configured to levitate the substrate over a top surface thereof; a first rotation mechanism configured to rotate the substrate over the main levitation unit so that an angle of an edge of the substrate with respect to a line direction of the laser light becomes a first angle in a plan view; a first conveyance mechanism configured to convey the substrate rotated by the first rotation mechanism in a first direction in a state in which the angle of the edge of the substrate is the first angle; and a second conveyance mechanism configured to convey, in order to change an irradiation place of the laser light on the substrate, the substrate conveyed by the first conveyance mechanism in a second direction in the state in which the angle of the edge of the substrate is the first angle.

A conveyance method according to an embodiment is a conveyance method for conveying a substrate by using a conveyance apparatus in order to irradiate the substrate with line-shaped laser light, in which the conveyance apparatus includes: a main levitation unit including an irradiation area disposed directly below an irradiation place of the laser light, and configured to levitate the substrate over a top surface thereof; a first rotation mechanism configured to rotate the substrate over the main levitation unit in a plan view; a first conveyance mechanism configured to convey the substrate in a first direction over the main levitation unit; and a second conveyance mechanism configured to convey the substrate in a second direction over the main levitation unit, and the conveyance method including the steps of: (A1) rotating, by the first rotation mechanism, the substrate over the main levitation unit so that an angle of the edge of the substrate with respect to a line direction of the laser light becomes a first angle; (A2) conveying, by the first conveyance mechanism, the substrate rotated by the first rotation mechanism in a first direction in a state in which the angle of the edge of the substrate is the first angle; and (A3) conveying, by the second conveyance mechanism, in order to change an irradiation place of the laser light on the substrate, the substrate conveyed by the first conveyance mechanism in a second direction in a state in which the angle of the edge of the substrate is the first angle.

According to an embodiment, a method for manufacturing a semiconductor device includes the steps of: (sa1) forming an amorphous film over a substrate; (sa2) loading the substrate with the amorphous film formed thereover onto a conveyance apparatus; and (sa3) irradiating the substrate with line-shaped laser light while conveying the substrate using the conveyance apparatus, and thereby annealing the amorphous film so that the amorphous film is crystallized into a crystallized film, the conveyance apparatus including: a first rotation mechanism configured to rotate the substrate over the main levitation unit so that an angle of the edge of the substrate with respect to a line direction of the laser light becomes a first angle in a plan view; a first conveyance mechanism configured to convey the substrate rotated by the first rotation mechanism in a first direction in a state in which the angle of the edge of the substrate is the first angle; and a second conveyance mechanism configured to convey, in order to change an irradiation place of the laser light on the substrate, the substrate conveyed by the first conveyance mechanism in a second direction in the state in which the angle of the edge of the substrate is the first angle.

According to an embodiment, a laser irradiation apparatus includes: a main levitation unit configured to levitate the substrate over a top surface thereof; a laser irradiation unit configured to irradiating the substrate with line-shaped laser light; a first rotation mechanism configured to rotate the substrate over the main levitation unit so that an angle of the edge of the substrate with respect to a line direction of the laser light becomes a first angle in a plan view; a first conveyance mechanism configured to convey the substrate rotated by the first rotation mechanism in a first direction in a state in which the angle of the edge of the substrate is the first angle; and a second conveyance mechanism configured to convey, in order to change an irradiation place of the laser light on the substrate, the substrate conveyed by the first conveyance mechanism in a second direction in the state in which the angle of the edge of the substrate is the first angle.

According to the above-described embodiments, it is possible to perform conveyance of a substrate suitable for a laser irradiation process.

### BRIEF DESCRIPTION OF DRAWINGS

FIG. 1 is a plan view schematically showing a configuration of a conveyance apparatus used in a laser irradiation apparatus;

FIG. 2 is a side cross-cross-sectional view schematically showing a laser irradiation apparatus;

FIG. 3 is a side cross-cross-sectional view schematically showing a laser irradiation apparatus;

FIG. 4 is a plan view for explaining a configuration before a substrate is irradiated with laser light;

FIG. 5 is a plan view for explaining a configuration during irradiation by laser light;

FIG. 6 is a plan view for explaining a conveyance direction and an inclination of a substrate;

FIG. 7 is a plan view for explaining a conveyance step in a conveyance apparatus;

FIG. 8 is a plan view for explaining a conveyance step in the conveyance apparatus;

FIG. 9 is a plan view for explaining a conveyance step in the conveyance apparatus;

FIG. 10 is a plan view for explaining a conveyance step in the conveyance apparatus;

FIG. 11 is a plan view for explaining a conveying process in the conveyance apparatus;

FIG. 12 is a plan view for explaining a conveying process in the conveyance apparatus;

FIG. 13 is a plan view for explaining a conveying process in the conveyance apparatus;

FIG. 14 is a plan view for explaining a conveying process in the conveyance apparatus;

FIG. 15 is a plan view for explaining a conveying process in the conveyance apparatus;

FIG. 16 is a plan view for explaining a conveying process in the conveyance apparatus;

FIG. 17 is a plan view for explaining a conveying process in a conveyance apparatus according to a modified example;

FIG. 18 is a plan view for explaining a conveying process in a conveyance apparatus according to a modified example;

FIG. 19 is a plan view for explaining a conveying process in a conveyance apparatus according to a modified example;

FIG. 20 is a plan view for explaining a conveying process in a conveyance apparatus according to a modified example;

FIG. 21 is a plan view for explaining a conveying process in a conveyance apparatus according to a modified example;

FIG. 22 is a plan view for explaining a conveying process in a conveyance apparatus according to a modified example;

FIG. 23 is a schematic view for explaining a rotation angle of a substrate.

FIG. 24 is a schematic view for explaining a rotation angle of a substrate.

FIG. 25 is a plan view schematically showing a configuration of a conveyance apparatus according to a second embodiment;

FIG. 26 is a plan view for explaining a conveyance step in the conveyance apparatus according to the second embodiment;

FIG. 27 is a plan view for explaining a conveyance step in the conveyance apparatus according to the second embodiment;

FIG. 28 is a plan view for explaining a conveyance step in the conveyance apparatus according to the second embodiment;

FIG. 29 is a plan view for explaining a protruding part of a substrate;

FIG. 30 is a plan view schematically showing a configuration of a conveyance apparatus according to another aspect according to the second embodiment;

FIG. 31 is a plan view schematically showing a configuration of a conveyance apparatus according to a third embodiment;

FIG. 32 is a plan view for explaining a conveyance step in the conveyance apparatus according to the third embodiment;

FIG. 33 is a plan view for explaining a conveyance step in the conveyance apparatus according to the third embodiment;

FIG. 34 is a cross-cross-sectional view showing a simplified configuration of an organic EL display device;

FIG. 35 is a cross-cross-sectional view showing a process in a method for manufacturing a semiconductor device according to an embodiment; and

FIG. 36 is a cross-cross-sectional view showing a process in the method for manufacturing the semiconductor device according to the embodiment.

### DESCRIPTION OF EMBODIMENTS

A conveyance apparatus according to an embodiment is used in a laser irradiation apparatus such as a laser annealing apparatus. The laser annealing apparatus is, for example, an ELA (Excimer Laser Anneal) apparatus that forms an LTPS (Low Temperature Poly-Silicon) film. A conveyance apparatus, a laser irradiation apparatus, a method, and a manufacturing method according to this embodiment will be described hereinafter with reference to the drawings.

### First Embodiment

### (Basic Configuration)

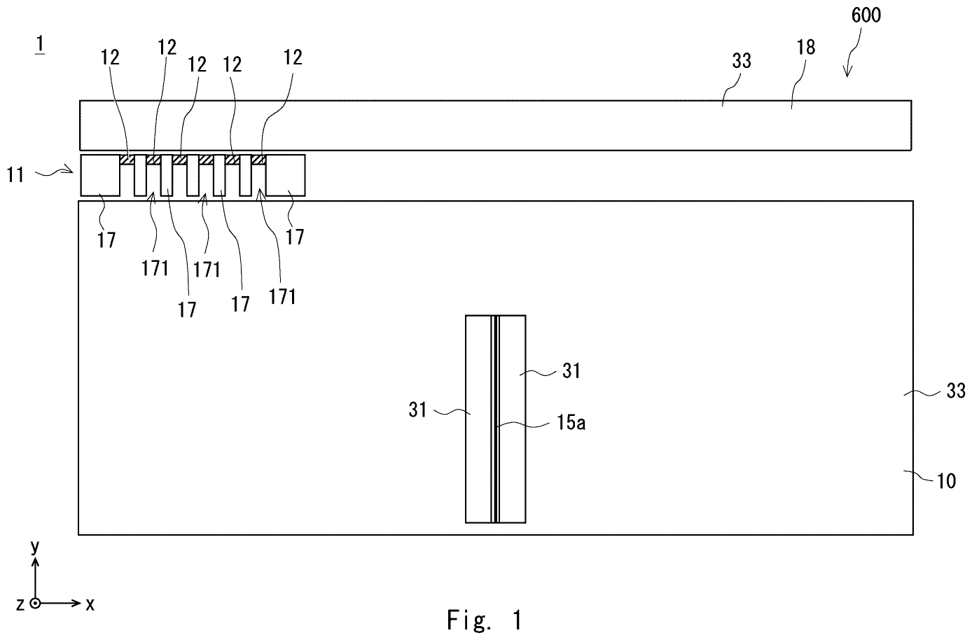

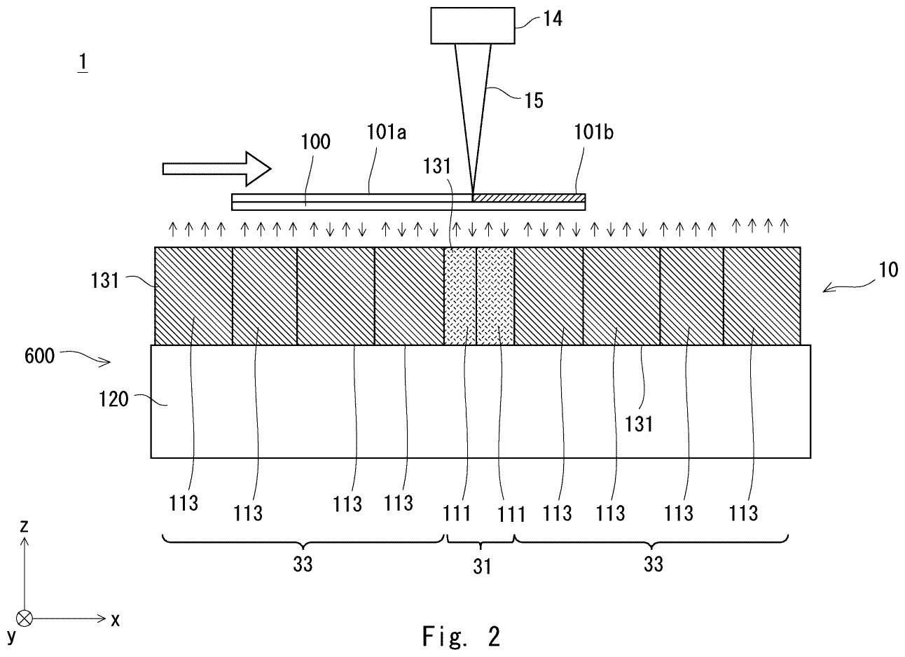

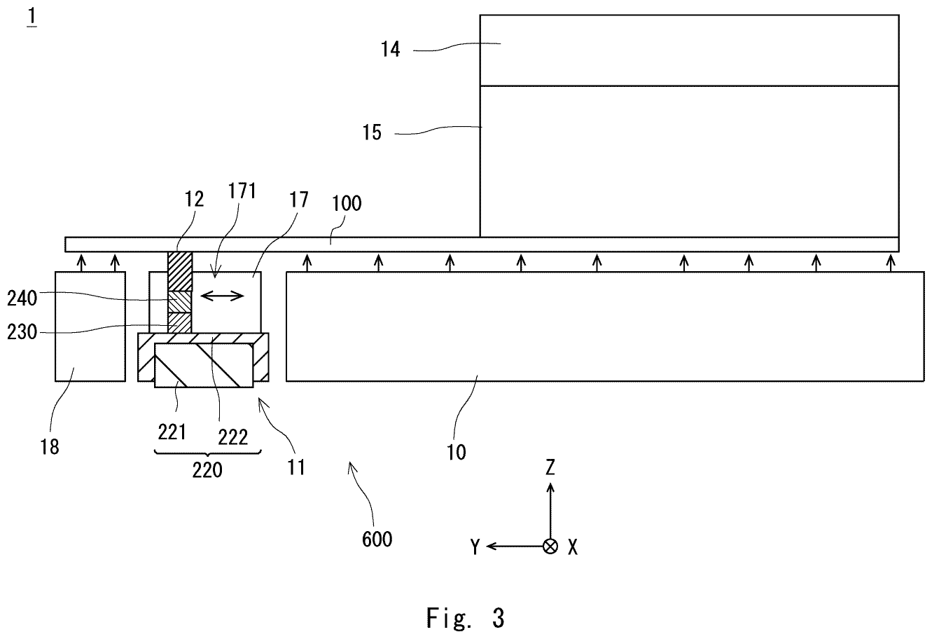

A fundamental configuration of a conveyance apparatus and a laser irradiation apparatus according to this embodiment will be described with reference to FIGS. 1 to 3. FIG. 1 is a plan view schematically showing a fundamental configuration of a conveyance apparatus 600. FIG. 2 is a side cross-sectional view schematically showing a configuration of a laser irradiation apparatus 1. FIG. 3 is a side cross-sectional view schematically showing the configuration of the laser irradiation apparatus 1.

Note that in the drawings described below, an xyz three-dimensional orthogonal coordinate system is shown as appropriate for the sake of simplifying the description. The z direction is a vertical direction, and the y direction is a line direction along a linear irradiation area 15a. The x direction is a direction perpendicular to the z and Y directions. That is, the y direction is the longitudinal direction (i.e., the long-side direction) of the linear irradiation area 15a, and the x direction is the lateral direction (i.e., the short-side direction) perpendicular to the longitudinal direction.

Note that FIGS. 1 to 3 are conceptual diagrams showing only the fundamental configuration of the conveyance apparatus 600 and the laser irradiation apparatus 1, and parts of the configuration thereof are omitted. For example, in FIG. 1, the conveyance apparatus 600 is shown in a simplified manner. Specifically, in FIG. 1, a laser irradiation unit 14, precision levitation units 111, and rough levitation units 113 are omitted.

As shown in FIGS. 1 to 3, the laser irradiation apparatus 1 includes a main levitation unit 10, a conveyance unit 11, and a laser irradiation unit 14. The main levitation unit 10 and the conveyance unit 11 constitute the conveyance apparatus 600. Further, the conveyance apparatus 600 may include an end levitation unit 18.

As shown in FIG. 2, the main levitation unit 10 is configured so that gas is ejected from the surface of the main levitation unit 10. The substrate 100 is levitated by the main levitation unit 10 over the top surface thereof. The substrate 100 is levitated as the gas ejected from the surface of the main levitation unit 10 is blown onto the bottom surface of the substrate 100. The substrate 100 is, for example, a glass substrate. When the substrate 100 is conveyed, the main levitation unit 10 adjusts the levitation height of the substrate 100 so that it does not collide with any of other mechanisms (not shown) disposed above the substrate 100.

The main levitation unit 10 is principally divided into a precision levitation area 31 and a rough levitation area 33. The precision levitation area 31 is an area including the irradiation area 15a of the laser light 15. That is, in the xy-plan view, the precision levitation area 31 is an area that coincides with the focal point (irradiation area 15a) of the laser light. The precision levitation area 31 is an area larger than the irradiation area 15a.

The rough levitation area 33 is an area adjacent to the precision levitation area 31. The rough levitation area 33 is, i.e., two rough levitation areas 33 are, arranged on both sides of the precision levitation area 31 in the x direction. In the xy-plan view, the rough levitation area 33 is an area that does not overlap the focal point (irradiation area 15a) of the laser light.

Each of the precision levitation units 111 and the rough levitation units 113 ejects gas (e.g., air) upward. Further, the gas ejected from the precision levitation units 111 and the rough levitation units 113 may be an inert gas such as nitrogen. The substrate 100 is levitated as the gas ejected from the surface of the main levitation unit 10 is blown onto the bottom surface of the substrate 100. As a result, the main levitation unit 10 and the substrate 100 are no longer contact with each other. Further, the precision levitation units 111 sucks the gas present between the substrate 100 and the main levitation unit 10. The rough levitation units 113 may be configured to suck gas in a manner similar to the precision levitation units 111, or may not be configured to suck the gas.

For example, a gas supply source(s) (not shown) for supplying gas is connected to the precision levitation units 111 and the rough levitation units 113. Further, a vacuum generation source(s) (not shown) for sucking gas is connected to the precision levitation units 111 and the rough levitation units 113. The gas supply source is a compressor, a gas cylinder, or the like, and supplies compressed gas. The vacuum generation source is a vacuum pump, an ejector, or the like.

The accuracy of the levitation height by the precision levitation units 111 is higher than that of the levitation height by the rough levitation units 113. Further, the substrate 100 is irradiated with laser light in the precision levitation area 31 having the highest accuracy of the levitation height. Note that a semi-precision levitation unit may be provided between the precision levitation unit 111 and the rough levitation unit 113. The accuracy of the levitation height by the semi-precision levitation unit is lower than that of the precision levitation unit 111 and higher than that of the rough levitation unit 113.

For example, high accuracy is required for the levitation height of the substrate 100 in the irradiation area 15a and the precision levitation area 31 therearound. Therefore, the precision levitation unit 111 capable of controlling the levitation height with high accuracy is used. The precision levitation unit 111 is a precision levitation unit formed of a porous element such as ceramic or a metal material.

Further, the precision levitation unit 111 ejects gas upward. Further, suction holes for sucking gas may be provided in the precision levitation unit 111. In the porous element, suction holes extending to its top surface are formed, e.g., machined, at predetermined intervals. The suction holes are minute holes and form a negative pressure between the substrate 100 and the precision levitation unit. Further, gas is ejected from almost the entire surface of the porous element except for the suction holes. The ejection surface that forms a positive pressure is formed over almost the entire surface except for the suction holes.

The rough levitation unit 113 is formed of a metal material. For example, the rough levitation unit 113 is formed of a metal block having a hollow part. Further, a plurality of ejection holes extending from the hollow part of the metal block to the top surface thereof are formed. Further, suction holes for sucking gas may be provided in the metal block. Note that the semi-precision levitation unit may be formed of a metal material as in the case of the rough levitation unit 113.

The rough levitation units 113 and the precision levitation units 111 are also collectively referred to as levitation unit cells 131. In the rough levitation area 33, a plurality of rough levitation units 113 are provided as levitation unit cells 131. In the precision levitation area 31, a plurality of precision levitation units 111 are provided as levitation unit cells 131. A semi-precision levitation area may be provided between the precision levitation area 31 and the rough levitation area 33.

The rough levitation units 113 and the precision levitation units 111 are fixed to a pedestal (not shown). The pedestal is, for example, a metal plate. The precision levitation units 111 and the rough levitation units 113 are fixed to the pedestal by, for example, bolts. The heights of the top surfaces of the precision levitation units 111 and the rough levitation units 113 are substantially equal to each other. That is, the top surface (levitation surface) of the main levitation unit 10 is substantially flat. The surface of the pedestal may be polished so as to have a predetermined flatness. Further, an internal space (not shown) serving as a flow path for ejecting or sucking gas may be provided inside the pedestal. The levitation unit cells 131 may suck or eject gas through the internal space of the pedestal.

The end levitation unit 18 is provided on the +y side of the main levitation unit 10. The end levitation unit 18 is disposed directly below the end of the substrate 100. Similarly to the main levitation unit 10, the end levitation unit 18 ejects gas onto the bottom surface of the substrate 100. The end of the substrate 100 is levitated by the gas ejected from the top surface of the end levitation unit 18. The end levitation unit 18 has a configuration similar to that of the rough levitation unit. The end levitation unit 18 is formed of a metal material having ejection holes or the like.

The conveyance unit 11 conveys the levitated substrate 100 in the conveyance direction. The conveyance unit 11 is provided at the end of the main levitation unit 10 in the +y direction. Specifically, the conveyance unit 11 is disposed between the main levitation unit 10 and the end levitation unit 18 in the y direction. As shown in FIG. 3, the conveyance unit 11 includes holding mechanisms 12, a movable levitation unit 17, an x-moving mechanism 220, y-moving mechanisms 230, and lifting/lowering mechanisms 240.

The holding mechanisms 12 hold the substrate 100. For example, the holding mechanism 12, i.e., each holding mechanism 12, can be formed by using a vacuum suction mechanism. The vacuum suction mechanism is formed of a metal material, a resin-based material, a porous material, or the like. Absorption grooves, absorption holes, or the like are formed in the top surface of the holding mechanism 12. The holding mechanism 12 may be formed of a porous material.

The holding mechanism 12 (the vacuum suction mechanism) is connected to an exhaust port (not shown) and the exhaust port is connected to an ejector, a vacuum pump, or the like. Therefore, since a negative pressure for sucking gas acts, i.e., is formed, in the holding mechanisms 12, the substrate 100 can be held by using the holding mechanisms 12.

The holding mechanisms 12 hold the substrate 100 by sucking the surface (bottom surface) of the substrate 100 opposite to the surface (top surface) thereof which is irradiated with the laser light 15, i.e., the surface of the substrate 100 opposed to the main levitation unit 10. In FIG. 1, the holding mechanisms 12 hold the end of the substrate 100 in the +y direction.

As shown in FIG. 3, the holding mechanisms 12 are supported by lifting/lowering mechanisms 240 for performing a sucking operation. The lifting/lowering mechanisms 240 lift and lower the holding mechanisms 12. Each of the lifting/lowering mechanisms 240 includes, for example, an actuator such as an air cylinder or a motor. Each of the lifting/lowering mechanisms 240 further includes a linear guide mechanism along the Z direction. Therefore, the lifting/lowering mechanisms 240 can move the holding mechanisms 12 up and down. For example, the holding mechanisms 12 suck the substrate 100 in a state in which they are lifted to a sucking position. Further, the holding mechanism 12 is lowered to a standby position in a state in which the sucking is cancelled, i.e., stopped.

A movable levitation unit 17 is disposed around each of the holding mechanisms 12. The movable levitation unit 17 ejects gas onto the substrate 100. The movable levitation unit 17 ejects gas onto the bottom surface of the substrate 100 in a manner similar to the main levitation unit 10. The end of the substrate 100 is levitated by the gas ejected from the top surface of the movable levitation unit 17. For example, the movable levitation unit 17 has a configuration similar to that of the rough levitation unit 113. The movable levitation unit 17 is made of a metal material having ejection holes or the like.

As shown in FIG. 1, the conveyance unit 11 includes a plurality of movable levitation units 17 and a plurality of holding mechanisms 12. The plurality of movable levitation units 17 are arranged in the x direction. The plurality of holding mechanisms 12 are arranged in the x direction. In the x direction, the movable levitation units 17 and the holding mechanisms 12 are alternately arranged. Therefore, movable levitation units 17 are arranged on both sides of a holding mechanism 12 in the x direction. A holding mechanism 12 is disposed in a space 171 between two movable levitation units 17 adjacent to each other.

In the xy-plan view, a space 171 has a rectangular shape with the long-side direction being parallel to the y direction and the short-side direction being parallel to the x direction. Note that although six movable levitation units 17 and six spaces 171 are provided in FIG. 1, the number of movable levitation units 17 and the number of spaces 171 may be only one or may be two or more. Each holding mechanism 12 sucks and holds the substrate 100. A holding mechanism 12 is arranged in each space 171. The positions of the plurality of holding mechanisms 12 in the y direction are the same as each other.

The y-moving mechanisms 230 moves the plurality of holding mechanisms 12 in the y direction. For example, the holding mechanisms 12 and the lifting/lowering mechanisms 240 are disposed over the y-moving mechanisms 230. That is, the y-moving mechanisms 230 movably support the holding mechanisms 12 and the lifting/lowering mechanisms 240. The y-moving mechanisms 230 includes an actuator such as a motor (not shown). The y-moving mechanisms 230 move the holding mechanisms 12 and the lifting/lowering mechanisms 240 in the y direction. As a result, the holding mechanisms 12 move the spaces 171 in the y direction. The plurality of holding mechanisms 12 move synchronously with each other. That is, the plurality of holding mechanisms 12 move at the same speed.

The x-moving mechanism 220 moves the plurality of holding mechanisms 12, the plurality of movable levitation units 17, the lifting/lowering mechanisms 240, and the y-moving mechanisms 230 in the x direction. For example, the x-moving mechanism 220 includes a guide part 221 and a movable part 222. The guide part 221 serves as a stage for movably supporting the movable part 222. The guide part 221 is provided along the x direction. The x-moving mechanism 220 includes an actuator such as a motor (not shown). By the driving of the actuator, the movable part 222 moves over the guide part 221 in the x direction.

Further, the y-moving mechanisms 230 are provided over the movable part 222. That is, the movable part 222 supports the y-moving mechanisms 230 in such a manner that they are movable in the y direction. In the movable part 222, a guide mechanism such as a guide groove(s) or a guide rail(s) may be formed along the y direction.

The movable part 222 slides in the x direction over the guide part 221. Further, the y-moving mechanisms 230 slide in the y direction over the movable part 222. In this way, the holding mechanisms 12 move in the x and y directions. Therefore, the conveyance unit 11 can convey the substrate 100 in the x and y directions. By adjusting the moving speeds of the substrate 100 in the x and y directions, the conveyance direction of the substrate 100 can be changed. That is, by increasing the ratio of the moving speed in the y direction to that in the x direction, the angle formed by the x direction and the conveyance direction can be increased. By setting the moving speed in the y direction to zero, the conveyance direction becomes parallel to the x direction.

Further, the movable part 222 supports the movable levitation unit 17. Therefore, the movable part 222 moves the movable levitation unit 17 together with the y-moving mechanisms 230 in the x direction. Therefore, the movable levitation unit 17, the y-moving mechanisms 230, the lifting/lowering mechanisms 240, and the holding mechanisms 12 move together with the movable part 222. The movable part 222 serves as a stage for movably supporting the y-moving mechanisms 230, the movable levitation unit 17, and the like.

As shown in FIG. 1, for example, the conveyance unit 11 is configured so as to slide the end of the main levitation unit 10 in the ty direction along the conveyance direction. Further, the x-moving mechanism 220 and the y-moving mechanisms 230 are controlled independently of each other. The conveyance speed and the conveyance direction of the substrate 100 can be controlled by adjusting the moving speeds of the x-moving mechanism 220 and the y moving mechanisms 230.

Each of the x-moving mechanism 220 and the y-moving mechanisms 230 may include, for example, an actuator such as a motor, a linear guide mechanism, an air bearing, and the like (not shown). The x-moving mechanism 220 and the y-moving mechanisms 230 are synchronized with each other, and move the holding mechanisms 12 in the x and y directions.

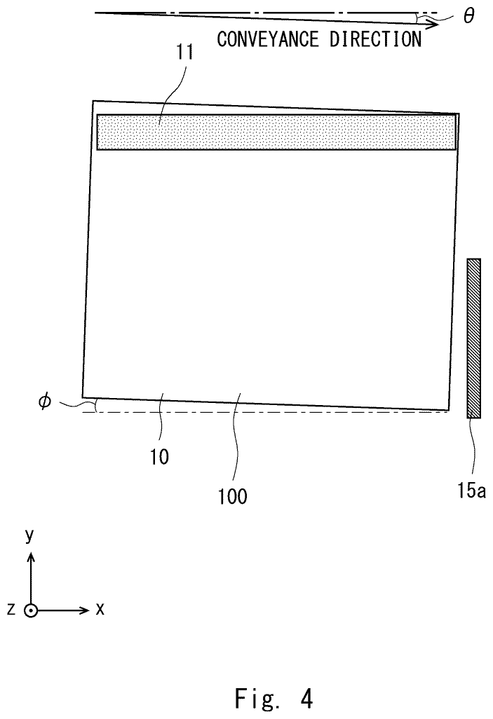

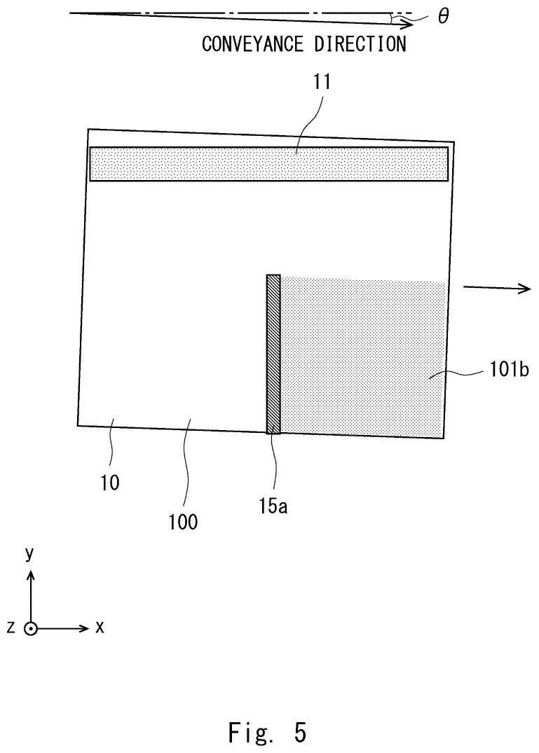

As shown in FIGS. 4 and 5, as the holding mechanisms 12 move along the conveyance direction, the substrate 100 is conveyed in the conveyance direction. The conveyance direction is inclined from the x direction. Further, in each of FIGS. 4 and 5, a straight line parallel to the x direction is indicated by a chain line. For example, when the angle between the x direction and the conveyance direction is represented by θ, the angle θ is larger than 0°. Then, by changing the moving speed in at least one of the x and y directions, the angle θ of the conveyance direction relative to the x direction can be changed. In this way, the substrate 100 can be conveyed at an angle suitable for the process. Further, when the y-moving mechanisms 230 are stopped, the angle θ can be set to 0° (θ=0°).

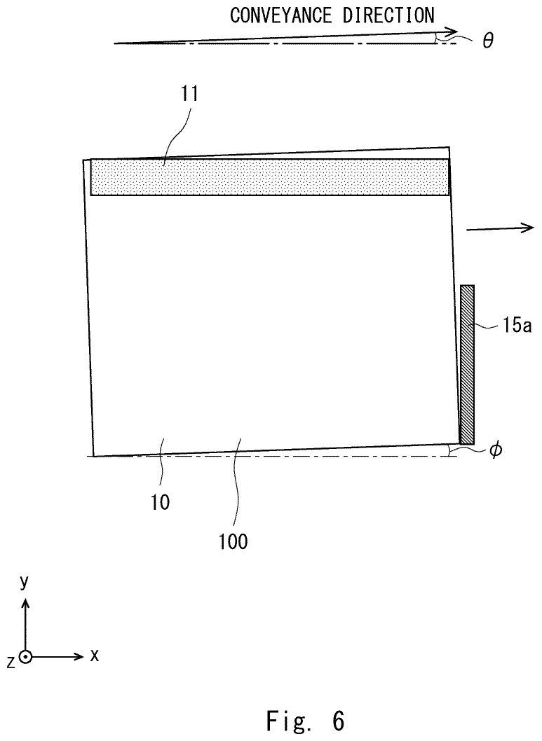

The angle θ of the conveyance direction can be adjusted by independently changing the moving speed in the x- or y direction. In this way, conveyance suitable for the process can be carried out. Further, as shown in FIG. 6, the moving direction of the y-moving mechanisms 230 can be made parallel to the y-axis positive direction. In this case, the sign, i.e., the plus/minus, of the angle θ of the conveyance direction can be changed. Specifically, when the angle θ in the configuration shown in FIG. 4 is defined as a positive value, the angle θ in the configuration shown in FIG. 6 becomes a negative value. That is, the angle θ becomes smaller than 0° in FIG. 6. The conveyance direction can be inclined so that the angle θ of the conveyance direction relative to the x direction becomes not only a positive value but also a negative value. For example, the angle θ can be varied in a range from −5° to +5°.

Further, as shown in FIG. 1, the main levitation unit 10 has a rectangular shape in the xy-plan view. Specifically, in the xy-plan view, the main levitation unit 10 has a rectangular shape having two sides parallel to the x direction and two sides parallel to the y direction. Further, the conveyance direction is inclined from the edge of the main levitation unit 10. In other words, the holding mechanisms 12 get closer to the main levitation unit 10 as they move in the +x direction. Further, the substrate 100 has a rectangular shape. Further, the substrate 100 is disposed so that its edge is inclined from the x and y directions. For example, the substrate 100 is disposed so that its edge is parallel to the conveyance direction. Alternatively, the substrate 100 may be disposed so that its edge is parallel to a direction inclined from the conveyance direction.

As shown in FIG. 4, an angle formed between the edge of the substrate 100 and the x direction is represented by φ. Note that in FIG. 4, the conveyance direction is parallel to the edge of the substrate 100, so that φ and θ coincide with each other. That is, φ is the same angle as θ. The edge of the substrate 100 on the upstream side in the conveyance direction of the conveyance unit 11 corresponds to the short side of the substrate 100. The angle of the short side of the substrate 100 is o with respect to the line direction of the laser light. Further, the angle of the edge of the substrate 100 relative to the conveyance direction can be adjusted by rotating the substrate 100 around the z-axis. For example, the substrate 100 can be rotated in a range of −5° to 5°. By rotating the substrate 100, φ can be adjusted within a range of ±5°. In this way, even when the angle θ formed by the x direction and the conveyance direction is changed, the conveyance direction and the direction of the edge of the substrate 100 can be made parallel to each other. Needless to say, the conveyance direction and the direction of the edge of the substrate 100 may be different from each other. That is, θ and φ may be angles different from each other.

As shown in FIG. 2, the substrate 100 is irradiated with laser light 15. Note that the irradiation area 15a of the laser light 15 in the substrate 100 has a line-like shape of which the longitudinal direction is parallel to the y direction. That is, in the irradiation area 15a, the y direction is the longitudinal direction (line direction) and the x direction is the lateral direction.

For example, the laser irradiation unit 14 includes an excimer laser light source or the like that generates laser light 15. The laser light 15 may be a pulsed laser light or a CW (Continuous Wave) laser light. Further, the laser irradiation unit 14 includes an optical system for guiding the laser light to the substrate 100. The laser irradiation unit 14 includes a lens(es) for concentrating the laser light 15 on the substrate 100. For example, the laser irradiation unit 14 includes a cylindrical lens for forming the linear irradiation area 15a. The substrate 100 is irradiated with line-shaped laser light, specifically, the laser light 15 (line beam) of which the focal point extends, i.e., stretches, in the y direction. The focal point of the laser light 15 is formed over the substrate 100. Therefore, in order to reduce in-plane variations, the levitation height needs to be accurate in the precision levitation area 31.

The substrate 100 is, for example, a glass substrate in which an amorphous film (amorphous silicon film 101a) is formed. The amorphous film can be crystallized by irradiating the amorphous film with laser light 15 and thereby performing an annealing process. For example, the amorphous silicon film 101a can be converted into a polycrystalline silicon film (polysilicon film 101b).

The laser irradiation apparatus 1 conveys the substrate 100 in the conveyance direction by holding the bottom surface of the substrate 100 using the conveyance unit 11 while levitating the substrate 100 using the levitation unit 10. Note that when the substrate 100 is conveyed, the conveyance unit 11 included in the laser irradiation apparatus 1 conveys the substrate 100 while the conveyance unit 11 is holding a part of the substrate 100 that does not overlap the irradiation area 15a in a plan view (i.e., as viewed in the z-direction). That is, as shown in FIG. 1, when the substrate 100 is conveyed in the conveyance direction, the part of the substrate 100 at which the main conveyance unit 11 holds the substrate 100 (which corresponds to the position of the holding mechanisms 12) does not overlap the irradiation area 15a.

For example, a planar shape of the substrate 100 is a quadrangle (a rectangular) having four sides and the main conveyance unit 11 (the holding mechanisms 12) holds only one of the four sides of the substrate 100. Further, the conveyance unit 11 (the holding mechanisms 12) holds a part of the substrate 100 that is not irradiated with laser light in a period during which the substrate 100 is being conveyed.

By the above-described configuration, it is possible to position the part of the substrate 100 at which the conveyance unit 11 holds the substrate 100 (which corresponds to the position of the holding mechanisms 12) and the irradiation area 15a away from each other. The irradiation area 15a is located roughly in a half of the substrate 100 in the −y direction, and the conveyance unit 11 holds the end the substrate 100 in the +y direction. It is possible to increase the distance between the place near the holding mechanisms 12 where the substrate 100 is bent widely and the irradiation area 15a. Therefore, it is possible to reduce the effect of the bending of the substrate 100 caused by the holding mechanisms 12 when laser light is applied to the substrate 100.

As shown in FIG. 4, the length of the irradiation area 15a in the y direction is roughly a half of the length of the substrate 100. As shown in FIG. 5, as the substrate 100 is conveyed, the laser light is applied to the area corresponding to the length of the irradiation area 15a. Then, in the area which has already been irradiated with the laser light, a polysilicon film 101b is formed.

When the substrate 100 passes the laser irradiation place 15a once, the amorphous silicon film 101a is crystallized in roughly a half of the area of the substrate 100. Then, after the substrate 100 is rotated about the z-axis by 180 degrees by a rotation mechanism (not shown), the conveyance unit 11 conveys the substrate 100 in the x direction. In this way, the substrate 100 passes through the laser irradiation place 15a, and the amorphous silicon film 101a is crystallized in the remaining half of the substrate 100. By moving the substrate 100 a plurality of times as described above, the amorphous silicon film 101a is converted into a polycrystalline silicon film 101b over the substantially entire area of the substrate 100.

Further, the conveyance direction is inclined from the x direction, which is perpendicular to the linear irradiation area 15a. That is, the substrate 100 is conveyed in the conveyance direction inclined from the edge of the rectangular substrate 100. By inclining the conveyance direction from the x direction in the plan view, it is possible to perform conveyance of a substrate suitable for a laser irradiation process. Therefore, it is possible to appropriately perform a process for crystallizing a silicon film, and thereby to improve the display quality. By the above-described configuration, for example, it is possible to prevent an occurrence of a moire.

Assume that, for example, the substrate 100 is a glass substrate for an organic EL (Electro-Luminescence) display device. When the display area of the organic EL display device is rectangular, the edges of the display area are parallel to the edges of the substrate 100. That is, the organic EL display device has a rectangular display area of which the short sides are parallel to the x and y directions. When the conveyance direction is parallel to the x direction, laser light is applied to the substrate 100 in a state in which the direction in which pixels are arranged is parallel to the irradiation area 15a.

As shown in this embodiment, it is possible to appropriately perform a laser irradiation process by inclining the conveyance direction from the x direction. The moving mechanism moves the holding mechanisms 12 in the conveyance direction inclined from the x direction perpendicular to the longitudinal direction of the linear irradiation area 15a in the plan view so as to change the irradiation place of the laser light over the substrate 100. In this way, it is possible to appropriately perform a process for crystallizing a silicon film. For example, it is possible to prevent an occurrence of a moire and thereby to improve the display quality.

Further, the conveyance unit 11 is capable of performing a two-axis operation. That is, the holding mechanisms 12 moves not only in the x direction but also in the y direction. In this case, it is necessary to widen the gap, i.e., clearance, between the main levitation unit 10 and the end levitation unit 18. That is, it is necessary to dispose the end levitation unit 18 away from the main levitation unit 10 in the Y direction. Even in such a case, the bending of the substrate 100 can be reduced by providing the movable levitation unit 17. Gas is ejected onto the bottom surface of the substrate 100 in the gap between the end levitation unit 18 and the main levitation unit 10. In this way, it is possible to prevent the substrate 100 from warping and thereby colliding with the main levitation unit 10 or structures therearound.

Further, the spaces 171 are provided between the movable levitation units 17. Further, the holding mechanisms 12 move in the y direction inside the spaces 171. Therefore, it is possible to adjust the conveyance direction of the substrate 100 with a simple configuration. Further, the plurality of spaces 171 are provided in the conveyance unit 11. Therefore, since a plurality of holding mechanisms 12 can hold the substrate 100, the substrate 100 can be reliably sucked and held.

### (Two-Axis Operation Conveyance Unit)

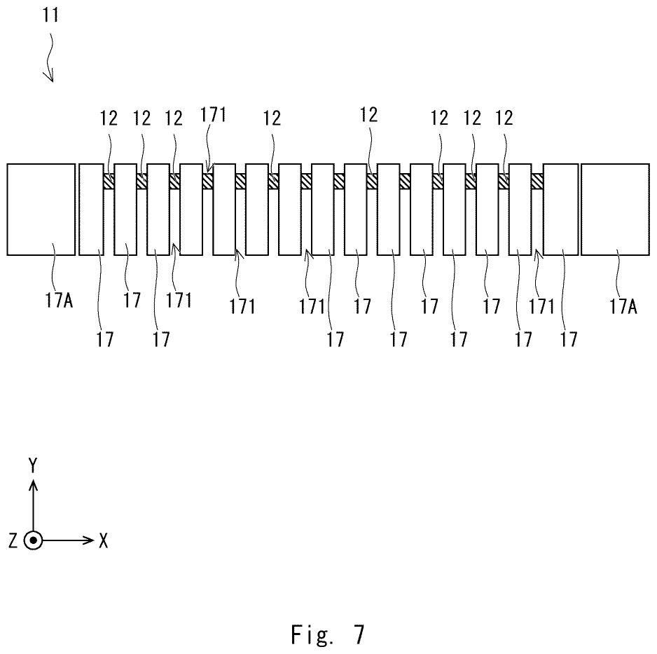

Next, an example of a detailed configuration of the conveyance unit 11 including the holding mechanisms 12 and the movable levitation units 17 will be described with reference to FIG. 7. FIG. 7 is a plan view showing a detailed configuration of the holding mechanisms 12 and the movable levitation units 17. The conveyance unit 11 performs a two-axis operation in the x- and y-axis directions.

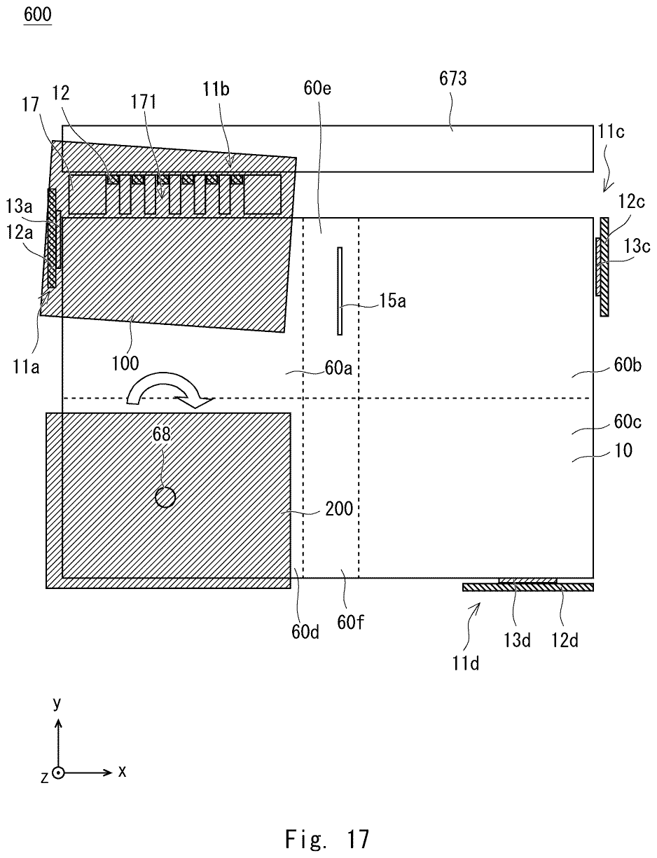

As shown in FIG. 7, the conveyance unit 11 includes a plurality of holding mechanisms 12 and a plurality of movable levitation units 17. In FIG. 17, 14 holding mechanisms 12, 15 movable levitation units 17, and two movable levitation units 17A are provided. The plurality of movable levitation units 17 are provided in a divided manner. The plurality of movable levitation units are arranged in the x direction with spaces 171 therebetween. The holding mechanisms 12 move in the y direction in the spaces 171 between the two movable levitation units.

According to this configuration, it is possible to manage the flatness of the movable levitation units 17. Specifically, since the movable levitation units 17 arranged on both sides of the holding mechanisms 12 are divided, the size of one movable levitation unit 17 can be reduced. It is possible to prevent the flatness of the levitation surface from deteriorating which would otherwise occur when the movable levitation units 17 are distorted due to the processing thereof. It is possible to achieve high flatness of the levitation surface, and thereby to prevent the levitation units and the substrate from colliding with each other during the conveyance of the substrate. Further, since a plurality of movable levitation units 17 are used, the height at which they are attached can be easily adjusted. The degree of freedom of the design can be improved.

Further, a space 171 can be provided in an area on the-y side of each holding mechanism 12. In this way, it is possible to eliminate areas which do not contribute much to the levitation of the substrate. For example, if a movable levitation unit 17 is provided in an area on the-y side of a holding mechanism 12, the size of the movable levitation unit 17 in the y direction in this area becomes small. That is, since a movable space for the holding mechanism 12 is provided, the size of the movable levitation unit 17 in the y direction is limited. Therefore, the number of ejection holes in the area on the −y side of the holding mechanism 12 becomes small. It is impossible to secure a sufficient size of area in which gas ejected from the ejection holes accumulates in minute gaps between the substrate 100 and the movable levitation units 17, there is a possibility that it does not contribute much to the levitation of the glass substrate. Therefore, it is possible to eliminate areas which do not contribute to the levitation of the substrate. In this way, it is possible to prevent the end of the substrate 100, which is being conveyed, from colliding with the movable levitation units 17.

In particular, in the case where the substrate 100 is a glass substrate for a display device or the like, the conveyance unit 11 is suitable for the conveyance of a substrate having a size G6 (1,850 mm×1,500 mm) or larger. For example, the conveyance unit 11 can efficiently convey a substrate such as one having a size G8.5 (2,500 mm×2,200 mm).

Further, the movable levitation unit 17A having a large width is provided at each of both ends in the y direction. That is, the plurality of movable levitation units 17 and the plurality of holding mechanisms 12 are arranged between the two movable levitation units 17A. In the y direction, the wide movable levitation unit 17A is provided on each of both sides of the movable levitation units 17. In this way, it is possible to prevent the edge of the substrate 100 from being located between movable levitation units 17. That is, it is possible to convey the substrate 100 in a state in which the edge of the substrate 100 is positioned directly above the movable levitation unit 17 or 17A.

### (Circulating Conveyance)

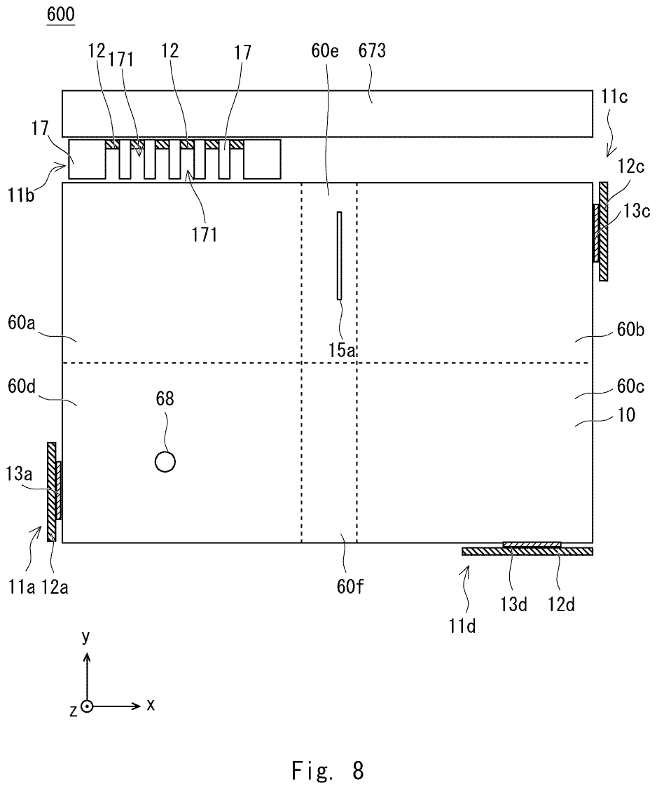

Next, an example of the detailed configuration of the conveyance apparatus 600 will be described with reference to FIG. 8. FIG. 8 is a plan view showing the configuration of the conveyance apparatus 600. Note that descriptions of components, functions, and the like similar to those described above with reference to FIGS. 1 to 7 will be omitted as appropriate. Note that in FIG. 8, the conveyance unit 11b is the above-described conveyance unit 11 which performs the two-axis operation.

The conveyance apparatus 600 includes a main levitation unit 10 and an end levitation unit 673. The main levitation unit 10 levitates a substrate 100, which is an object to be processed, (not shown in FIG. 8). In the plan view, the main levitation unit 10 has a rectangular shape. The main levitation unit 10 includes two sides parallel to the y direction and two sides parallel to the x direction. The end levitation unit 673 levitates an end of the substrate protruding beyond the main levitation unit 10.

Here, for the sake of explanation, the main levitation unit 10 is divided into six areas 60a to 60f in the plan view. Specifically, the main levitation unit 10 includes first to fourth areas 60a to 60d, a process area 60e, and a passage area 60f. The first area 60a is a rectangular area including a corner on the-x side and the ty side (i.e., upper-left corner in FIG. 8). The second area 60b is a rectangular area including a corner on the +x side and the ty side (i.e., upper-right corner in FIG. 8). The third area 60c is a rectangular area including a corner on the +x side and the −y side (i.e., lower-right corner in FIG. 8). The fourth area 60d is a rectangular area including a corner on the −x side and the −y side (i.e., lower-left corner in FIG. 8).

The process area 60e is a rectangular area disposed between the first and second areas 60a and 60b. The process area 60e is an area including the irradiation area 15a to which laser light is applied. The passage area 60f is a rectangular area located between the third and fourth areas 60c and 60d.

The half of the area of the main levitation unit 10 on the +y side (i.e., the upper half area in FIG. 4) is composed of, in the order from the −x side (i.e., from the left side in FIG. 8), the first area 60a, the process area 60e, and the second area 60b. The half of the area of the main levitation unit 10 on the −y side (i.e., the lower half area in FIG. 8) is composed of, in the order from the +x side, the third area 60c, the passage area 60f, and the fourth area 60d.

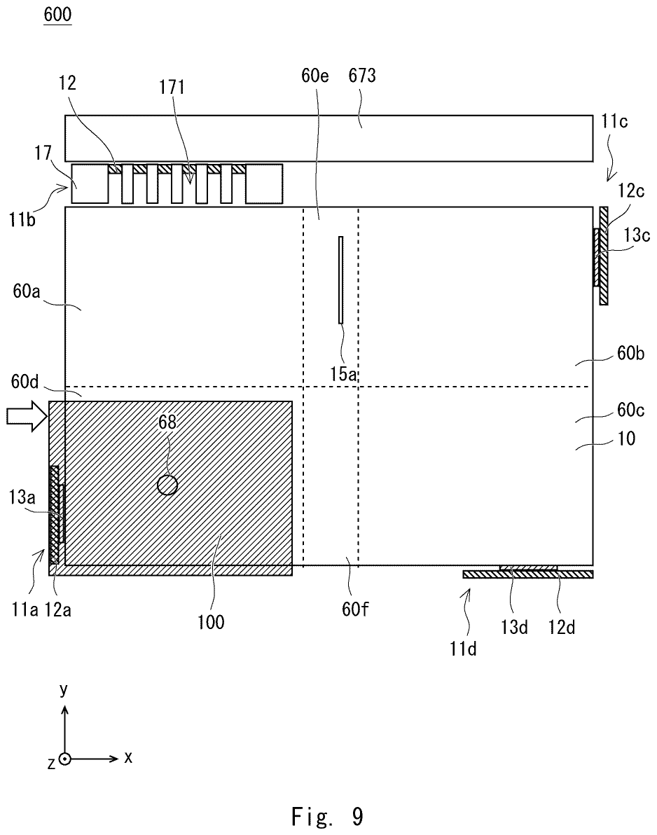

Further, the fourth area 60d serves as a carry-in area to which the substrate 100 (FIG. 9) is carried in and also a carry-out area from which the substrate 100 is carried out. For example, a loading machine such as a loading robot (not shown) is provided on the-x side of the fourth area 60d. Then, the loading machine carries in the substrate 100 to the fourth area 60d. Similarly, the loading machine carries out the substrate disposed in the fourth area 60d.

The main levitation unit 10 includes a rotation mechanism 68.

The rotation mechanism 68 rotates the substrate. The rotation mechanism 68 is provided in the fourth area 60d. The operation of the rotation mechanism 68 will be described later.

The end levitation unit 673 is disposed on the +y side of the main levitation unit 10. The end levitation unit 673 corresponds to the end levitation unit 18 shown in FIG. 1. The end levitation unit 673 is disposed along the edge of the main levitation unit 10 on the +y side. That is, the end levitation unit 673 is disposed along the x direction. The conveyance unit 11b is disposed in such a manner that it can move in the gap between the main levitation unit 10 and the end levitation unit 673.

Note that the conveyance unit 11b has a configuration similar to that of the conveyance unit 11 shown in FIGS. 1 and 3. Although the configuration of the conveyance unit 11b is shown in a simplified manner in FIG. 8 and the like, it has a configuration similar to that shown in FIGS. 1 and 3 and the like. Therefore, the conveyance unit 11b includes the holding mechanisms 12, the x-moving mechanism 220, the y-moving mechanisms 230, and the like shown in FIG. 3 and the like. The conveyance unit 11b is capable of performing a two-axis operation and moves the substrate 100 in the x and y directions. Therefore, the conveyance direction of the substrate 100 is inclined from the x direction.

Each of the conveyance units 11a, 11c and 11d is different from the conveyance unit 11 shown in FIG. 1, and is capable of only a one-axis operation. Specifically, each of the conveyance units 11a and 11c holds the substrate 100 and conveys it only in the y direction. The conveyance unit 11d holds the substrate 100 and conveys it only in the x direction. Each of the conveyance units 11a, 11c and 11d has a holding mechanism for vacuum-sucking the substrate 100 and a moving mechanism for moving the holding mechanism.

The conveyance unit 11a is disposed on the-x side of the main levitation unit 10. The conveyance unit 11b is disposed on the +y side of the main levitation unit 10. The conveyance unit 11c is disposed on the +x side of the main levitation unit 10. The conveyance unit 11d is disposed on the −y side of the main levitation unit 10.

The conveyance unit 11a includes a holding mechanism 12a and a moving mechanism 13a. Similarly, the conveyance unit 11c includes a holding mechanism 12c and a moving mechanism 13c, and the conveyance unit 11d includes a holding mechanism 12d and a moving mechanism 13d. Each of the holding mechanisms 12a, 12c and 12d sucks and holds the substrate 100. The moving directions of the moving mechanisms 13a and 13c are parallel to the y direction. The moving direction of the moving mechanism 13d is parallel to the x direction.

Further, each of the conveyance units 11a, 11c and 11d, and the rotation mechanism 68 includes a lifting/lowering mechanism for moving the substrate 100 up and down (not shown). For example, when the substrate 100 is received, the conveyance units 11a, 11c and 11d, and the rotation mechanism 68 rise to the receiving positions, and then suck and hold the substrate 100. When the substrate 100 is handed over, the conveyance units 11a, 11c and 11d, and the rotation mechanism 68 release the sucking, and then lower the substrate 100.

As shown in FIG. 8, in the irradiation area 15a of the laser light, the y direction is the longitudinal direction. That is, a linear irradiation area 15a of which the longitudinal direction is parallel to the y direction is formed. The substrate 100 is irradiated with the laser light while the substrate 100 is being conveyed in the conveyance direction. A laser irradiation process is performed while the substate is moving from the first area 60a to the second area 60b. In this embodiment, the amorphous silicon film is also converted into a polysilicon film by irradiating the substrate with laser light from the laser light source.

Note that in the main levitation unit 10, the precision levitation unit 111 shown in FIG. 2 is disposed in the area including the irradiation area 15a and the periphery thereof. The accuracy of the levitation height by the precision levitation unit 111 is higher than that of the rough levitation unit 113 (see FIG. 2). Therefore, in the process area 60e, which includes the irradiation area 15a, the laser light is applied to the substrate 100 which is being levitated at a levitation height the accuracy of which is higher than that in the other areas 60a-60d and 60f. In this way, it is possible to apply the laser light to the substrate 100 in a stable manner. Further, the areas other than the irradiation area 15a, such as the passage area 60f, the third area 60c, and the fourth area 60d, are manufactured without using an expensive precision levitation unit 111. Therefore, the cost of the apparatus can be reduced.

Note that the shapes of the areas 60a to 60f are not limited to rectangles. There may be areas where no levitation unit cell 131 is provided in parts of the areas 60a to 60f. That is, gas may not be ejected onto the substrate 100 in parts of the areas 60a to 60f. For example, an area where no levitation unit cell 131 is provided may be provided in the central part of the main levitation unit 10.

The conveyance unit 11b includes a movable levitation unit 17. Each of the conveyance units 11a, 11c and 11d includes no movable levitation unit 17. Therefore, the width of the conveyance unit 11b is wider than those of the conveyance units 11a, 11c and 11d. For example, the width of the conveyance unit 11b in the y direction is larger than that of the conveyance unit 11d in the y direction. Similarly, the width of the conveyance unit 11b in the y direction is larger than those of the conveyance units 11a, 11c in the x direction.

A procedure of a conveyance method using the main levitation unit 10 will be described with reference to FIGS. 9 to 16. In this example, the fourth area 60d is used as a place where the substrate 100 is carried in and carried out. Further, the substrate 100 carried into the fourth area 60d is conveyed from one area to another in the order of the first area 60a, the process area 60e, the second area 60b, the third area 60c, the passage area 60f, and the fourth area 60d. That is, the substrate 100 is moved in a circulating manner along the edges of the main levitation unit 10. In this example, the substrate 100 is moved in a circulating manner twice so that the entire area of the substrate 100 is irradiated with the laser light. That is, the substrate 100 is conveyed so that it is moved in a circulating manner twice over the main levitation unit 10. By doing so, substantially the entire surface of the substrate 100 is irradiated with the laser light.

As shown in FIG. 9, the substrate 100 is carried into the fourth area 60d. The substrate 100 carried into the fourth area 60d is being levitated by the main levitation unit 10. That is, the central part of the substrate 100 is being levitated by the main levitation unit 10.

The fourth area 60d is an area where the substrate 100 is carried in and carried out. The rotation mechanism 68 is provided in the fourth area 60d. For example, a through hole in which the rotation mechanism 68 is disposed is provided in the fourth area 60d of the main levitation unit 10. Further, the rotation mechanism 68 extends in the z direction and penetrates the main levitation unit 10. When a conveyance robot or the like (not shown) carries in the substrate 100 over the fourth area 60d of the main levitation unit 10, the rotation mechanism 68 receives the substrate 100. In FIG. 9, the edge of the substrate 100 is parallel to the x and y directions. More specifically, in FIG. 9, the long side of the rectangular substrate 100 is parallel to the x direction, and the short side thereof is parallel to the y direction.

The rotation mechanism 68 holds the substrate 100. For example, the rotation mechanism 68 includes a sucking and holding mechanism for sucking the substrate 100, a rotary motor for rotating the sucking and holding mechanism, and a lifting/lowering function for lifting/lowering the sucking and holding mechanism. The sucking and holding mechanism of the rotation mechanism 68 is similar to the holding mechanism 12 of the conveyance unit 11. The rotation mechanism 68 is disposed directly below the central part of the substrate 100. The rotation axis of the rotation mechanism 68 is parallel to the z-axis. The rotation mechanism 68 rotates the substrate 100 around the z-axis.

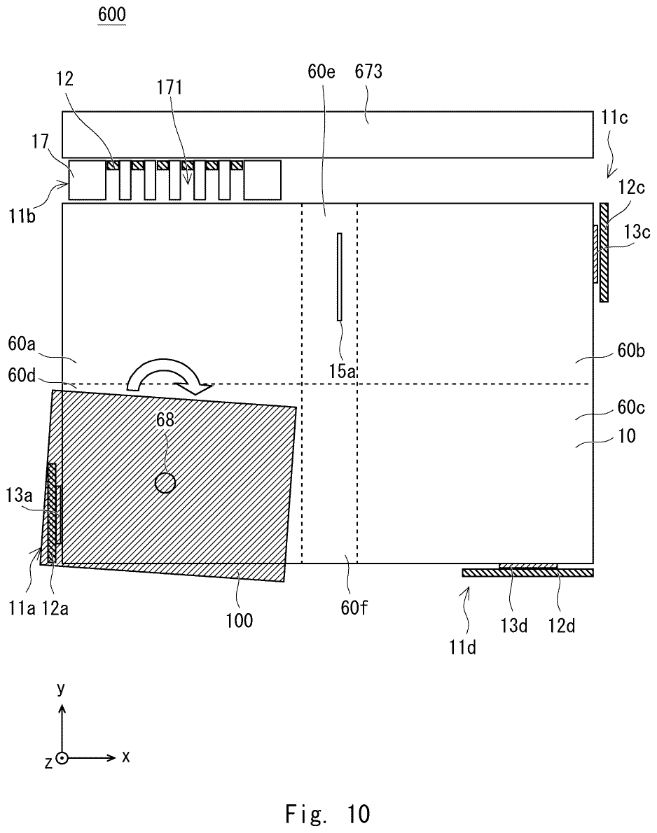

As shown in FIG. 10, in the XY-plan view, the rotation mechanism 68 rotates the substrate 100 (indicated by an outlined arrow in FIG. 10). As a result, the substrate 100 is oriented at the angle for the laser irradiation process. Note that the substrate 100 is rotated so that the edges of the substrate 100 are not parallel to the line direction of the laser light. For example, in FIG. 9, the two edges of the substrate 100 are orthogonal to the Y direction. The rotation mechanism 68 rotates the substrate 100 from the state shown in FIG. 9 by a small angle of 5 degrees or smaller.

As a result, the edges of the substrate 100 are not parallel to the Y and X directions. Specifically, the long side of the substrate 100 is inclined from the x direction by about 5°, and the short side of the substrate 100 is inclined from the y direction by about 5°.

In the following description, a state in which the edges of the substrate 100 are parallel to the x or y direction as shown in FIG. 9 is referred to as a parallel state. Further, a state in which the rotation mechanism 68 has rotated the substrate 100, and the edges of the substrate 100 are inclined from the x and y directions is referred to as an inclined state. That is, as the rotation mechanism 68 rotates the substrate 100, the substrate 100, which has been in the parallel state until then, becomes the inclined state. In FIG. 10, the substrate 100 is in the parallel state. The rotation mechanism 68 has rotated the substrate 100 so that the two edges of the substrate 100 become parallel to the conveyance direction of the conveyance unit 11b.

When the rotation of the rotation mechanism 68 is finished, the substrate 100 is handed over from the rotation mechanism 68 to the conveyance unit 11a. The conveyance unit 11a rises, and sucks and holds the substrate 100. The rotation mechanism 68 releases the sucking and holding, and descends. As a result, the substrate 100 is handed over from the rotation mechanism 68 to the holding mechanism 12a. The conveyance unit 11a sucks and holds the end of the substrate 100 on the −x side.

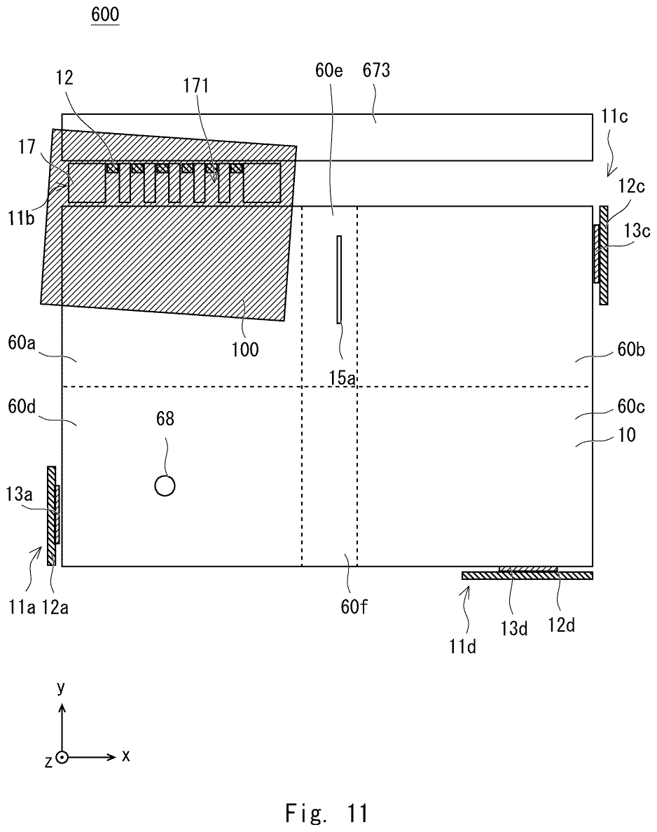

When the conveyance unit 11a conveys the substrate 100 in the ty direction, it becomes the state shown in FIG. 11. The conveyance unit 11a moves along the edge of the main levitation unit 10 on the −x side. The substrate 100 reaches a position directly above the conveyance unit 11b and the end levitation unit 673. The substrate 100 moves from the fourth area 60d to the first area 60a.

The substrate 100 is handed over from the conveyance unit 11a to the conveyance unit 11b. The conveyance unit 11b rises, and sucks and holds the substrate 100. The conveyance unit 11a releases the sucking and holding, and descends. As a result, the substrate 100 is handed over from the holding mechanism 12a to the holding mechanism 12. The conveyance unit 11b sucks and holds the end of the substrate 100 on the ty side. The conveyance unit 11b holds a part of the substrate 100 located on the inner side of the part thereof located above the end levitation unit 673.

The edge of the substrate 100 on the ty side and its periphery are positioned directly above the end levitation unit 673. Gas ejected from the end levitation unit 673 is blown onto the edge of the substrate 100 on the ty side and its periphery. The substrate 100 is being levitated by the main levitation unit 10, the movable levitation unit 17, and the end levitation unit 673. That is, the central part of the substrate 100 is being levitated by the main levitation unit 10. The end of the substrate 100 on the +y side is being levitated by the end levitation unit 673.

Note that the conveyance unit 11b includes the movable levitation unit 17 as shown in FIGS. 1 to 3. When the conveyance unit 11a conveys the substrate 100, the end of the substrate 100 on the +y side passes through the gap between the main levitation unit 10 and the end levitation unit 673. During this process, the movable levitation unit 17 ejects gas onto the substrate 100. In this way, it is possible to prevent the substrate 100 from bending and colliding with the edge of the main levitation unit 10 or the end levitation unit 673, or a structure therearound. As described above, there are cases where the gap between the end levitation unit 673 and the main levitation unit 10 is wide. Even in such a case, it is possible to prevent the substrate 100 from bending by providing the movable levitation unit 17 in the conveyance unit 11b.

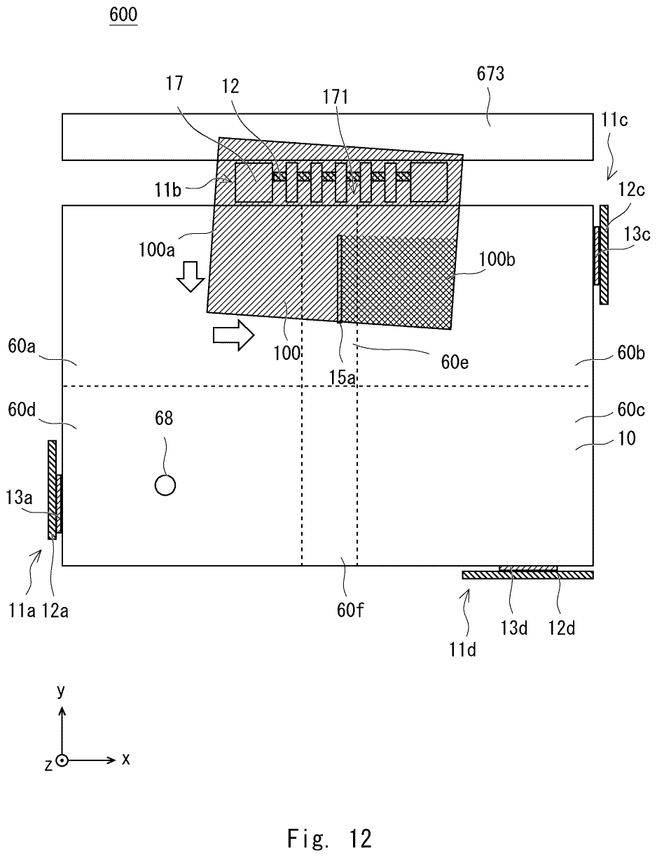

Next, as shown in FIG. 12, the conveyance unit 11b conveys the substrate 100 in the conveyance direction. As a result, the substrate 100 passes through the process area 60e. In this process, in the xy plan view, the holding mechanism 12 moves in the direction inclined from the x direction through the gap between the main levitation unit 10 and the end levitation unit 673. In this way, substantially a half of the area of the substrate 100 passes through the irradiation area 15a. The laser light is applied to the substrate 100, which is moving in the direction inclined from the x direction perpendicular to the irradiation area 15a. Note that in the substrate 100, the area that has already been irradiated with the laser light is referred to as an irradiated area 100b, and the area that has not yet irradiated with the laser light is referred to as an unirradiated area 100a. A polysilicon film 101b is formed in the irradiated area 100b as shown in FIG. 5.

Note that the holding mechanism 12 moves in the −y direction, and the holding mechanisms 12 and the movable levitation units 17 move in the +x direction. The substrate 100 is conveyed in a conveyance direction which is inclined from the x direction. The moving speed of the holding mechanism 12 in the y direction is lower than that of the holding mechanism 12 in the x direction. For example, the substrate 100 is conveyed in a conveyance direction inclined from the x direction of the irradiation area 15a by about 5 degrees. The edges of the substrate 100 are parallel to the conveyance direction of the conveyance unit 11b.

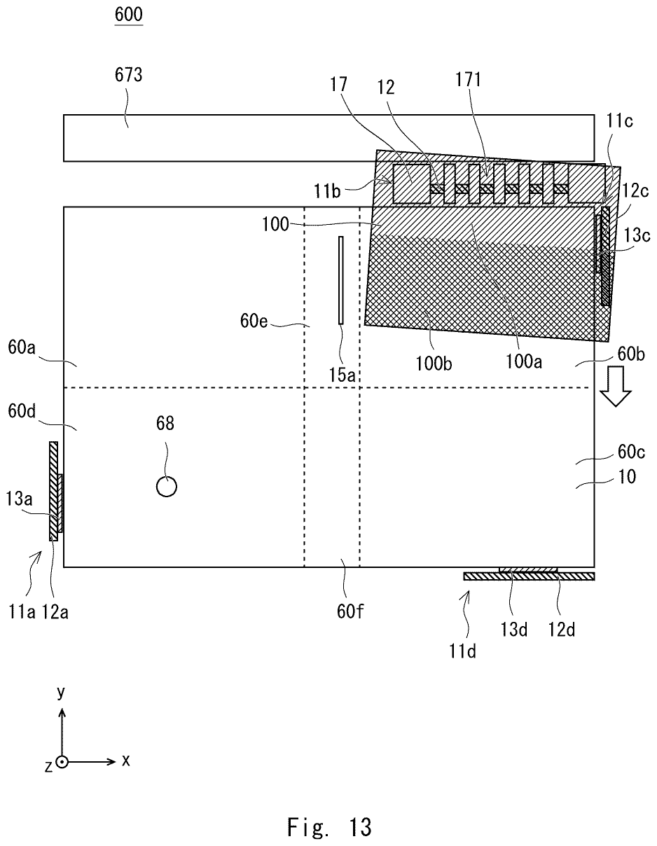

When the conveyance unit 11b further moves the substrate 100 in the conveyance direction, it becomes a configuration shown in FIG. 13. The substrate 100 passed through the irradiation area 15a and has already moved to the second area 60b. In the substrate 100, substantially a half of the area becomes an irradiated area 100b, and the remaining substantial half of the area remains as the unirradiated area 100a. In FIG. 13, the irradiated area 100b is the area on the-y side of the substrate 100, and the unirradiated area 100a is the area on the ty side of the substrate 100.

When the conveyance of the conveyance unit 11b is finished, the substrate 100 is handed over from the conveyance unit 11b to the conveyance unit 11c. The conveyance unit 11c rises, and sucks and holds the substrate 100. The conveyance unit 11b releases the sucking and holding, and descends. As a result, the substrate 100 is handed over from the holding mechanism 12 to the holding mechanism 12c. The conveyance unit 11c sucks and holds the end of the substrate 100 on the +x side.

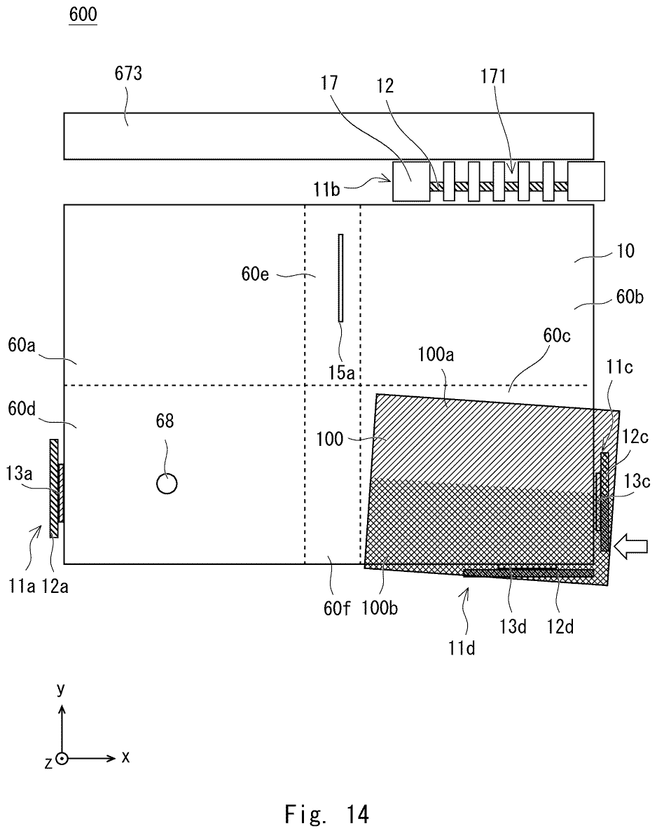

The conveyance unit 11c conveys the substrate 100 in the −y direction (indicated by an outlined arrow shown in FIG. 13). When the conveyance unit 11c conveys the substrate 100 from the second area 60b to the third area 60c, it becomes a configuration shown in FIG. 14.

When the conveyance of the conveyance unit 11c is finished, the substrate 100 is handed over from the conveyance unit 11c to the conveyance unit 11d. The conveyance unit 11d rises, and sucks and holds the substrate 100. The conveyance unit 11c releases the sucking and holding, and descends. As a result, the substrate 100 is handed over from the holding mechanism 12c to the holding mechanism 12d. The conveyance unit 11d sucks and holds the end of the substrate 100 on the −y side.

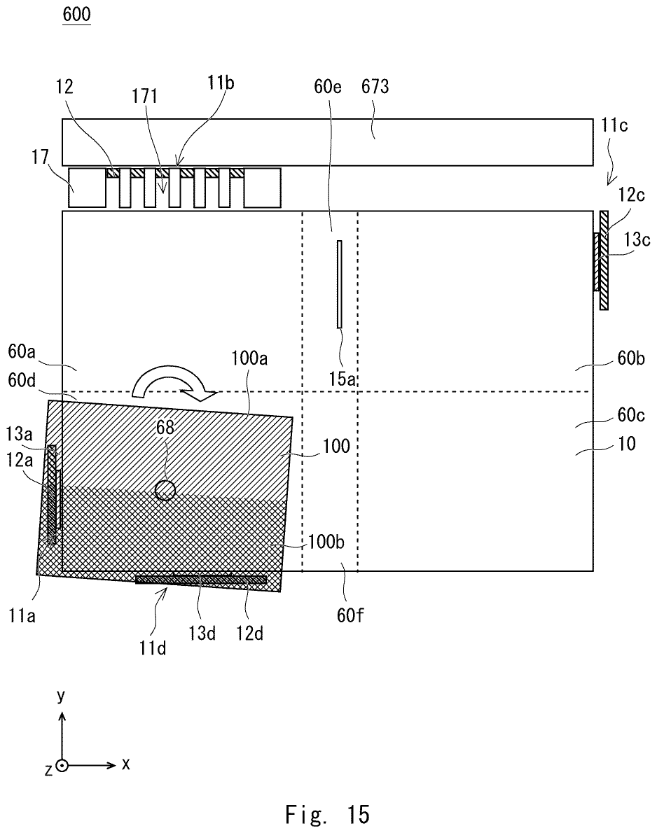

The conveyance unit 11d conveys the substrate 100 in the −x direction (indicated by an outlined arrow shown in FIG. 14). When the conveyance unit 11d conveys the substrate 100 from the third area 60c to the fourth area 60d, it becomes a configuration shown in FIG. 15.

When the conveyance of the conveyance unit 11d is finished, the substrate 100 is handed over from the conveyance unit 11d to the rotation mechanism 68. The rotation mechanism 68 rises, and sucks and holds the substrate 100. The conveyance unit 11d releases the sucking and holding, and descends. As a result, the substrate 100 is handed over from the holding mechanism 12d of the conveyance unit 11d to the rotation mechanism 68. The rotation mechanism 68 sucks and holds the central part of the substrate 100.

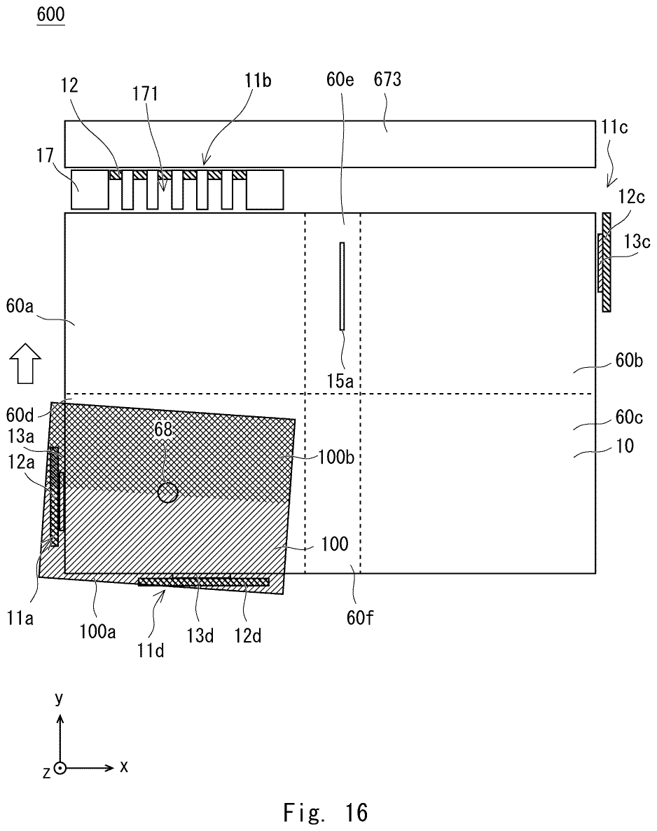

Next, the rotation mechanism 68 rotates the substrate 100 around the z-axis by 180° (indicated by an outlined arrow shown in FIG. 15). As a result, it becomes a configuration shown in FIG. 16. The irradiated area 100b becomes the area on the ty side of the substrate 100, and the unirradiated area 100a becomes the area on the −y side of the substrate 100. When the rotation mechanism 68 rotates the substrate 100, the substrate 100 is handed over from the rotation mechanism 68 to the holding mechanism 12a.

Then, as in FIGS. 11 to 15, the substrate 100 is conveyed. That is, the substrate 100 is moved in a circulating manner over the main levitation unit 10. As the conveyance unit 11a conveys the substrate 100 in the ty direction, it is moved from the fourth area 60d to the first area 60a. As the conveyance unit 11b conveys the substrate 100 in the +x and −y directions, the substrate 100 is moved from the first area 60a to the second area 60b.

The substrate 100 in the inclined state passes through the process area 60e by the conveyance of the conveyance unit 11b. The laser light is also applied to the part which was the unirradiated area 100a in the first round of the conveyance. The entire area of the substrate 100 is irradiated with the laser light. As the conveyance unit 11c conveys the substrate 100 in the −y direction, it is moved from the second area 60b to the third area 60c. As the conveyance unit 11d conveys the substrate 100 in the −x direction, the substrate 100 is moved from the third area 60c to the fourth area 60d.

As the conveyance apparatus 600 conveys the substrate 100, which is in the inclined state, in a circulating manner twice, the entire area of the substrate 100 is irradiated with the laser light. Then, a loading machine (not shown) taken out the substrate 100, which has been levitated over the main levitation unit 10. With this, the laser irradiation process is finished. Note that the rotation mechanism 68 may rotate the substrate 100 before the loading machine carries out the substrate 100 from the conveyance apparatus 600. That is, the loading machine may carry out the substrate 100 in the parallel state.

As describe above, the rotation mechanism 68 rotates the substrate 100 by 180°. When the substrate 100 passes through the process area 60e for the second time, the laser light is applied to the remaining half of the substate, i.e., the unirradiated area 100a, which was not irradiated with the laser light when the substrate 100 passed through the process area 60e for the first time. Then, the substrate 100, which has become the inclined state in the fourth area 60d, is conveyed in a circulating manner.

As described above, the substrate 100 in the inclined state is moved along the edges of the main levitation unit 10 in a circulating manner twice. Since the substrate 100 is rotated 180° between the first laser irradiation and the second laser irradiation, substantially the entire surface of the substrate 100 is irradiated with the laser light. Note that the place where the substrate 100 is rotated is not limited to the fourth area 60d. For example, it may be rotated in the second area 60b, the third area 60c, the first area 60a, or the like.

The substrate 100 in the inclined state is successively conveyed from the first area 60a. The angle of the substrate 100 during the laser-light irradiation is determined by the rotation angle by the rotation mechanism 68. In the plan view, the angle of the edge of the substrate 100 shown in FIG. 10 coincides with the angle of the edge of the substrate 100 shown in FIG. 12. The conveyance units 11a and 11b convey the substrate 100 in the inclined state. Then, as the conveyance unit 11b conveys the substrate 100 in an oblique direction, the substrate 100 is irradiated with the laser light. In this process, the direction of the edges of the substrate 100 is parallel to the conveyance direction of the conveyance unit 11b.

As described above, the rotation mechanism 68 rotates the substrate 100 so that it is oriented at the angle for the laser-light irradiation. That is, the angle of the substrate 100 during the laser irradiation is defined by the rotation angle of the rotation mechanism 68. Then, the substrate 100, which has become the inclined state in the fourth area 60d, is conveyed in a circulating manner. The above-described configuration eliminates the need to provide the alignment mechanism disclosed in Patent Literature 1 in the first area 60a. As a result, the configuration of the apparatus can be simplified. Further, since the need for the process for handing over the substrate 100 to the alignment mechanism and performing the alignment is eliminated, the processing time can be shortened compared with that required in the configuration disclosed in Patent Literature 1. Since the tact time can be shortened, the productivity can be improved.

The substrate 100 is rotated by the rotation mechanism 68 so that the angle of the substrate becomes the angle for the laser irradiation. Specifically, the rotation mechanism 68 rotates the substrate 100 twice in the two rounds of the circulating conveyance. Further, the number of times the substrate 100 is rotated can be reduced. The alignment process performed by the alignment mechanism disclosed in Patent Literature 1 can be omitted. Therefore, the configuration of the apparatus can be simplified, and the processing time can be shortened.

### (Modified Example 1)

A conveyance operation performed by a conveyance apparatus 600 according to Modified Example 1 will be described with reference to FIGS. 17 to 22. FIGS. 17 to 22 are plan views for explaining a conveyance operation according to the modified example. In the modified example, two substrates are simultaneously levitated over the main levitation unit 10. That is, two substrates are simultaneously conveyed.

In the following description, two substrates are shown as substrates 100 and 200 in order to distinguish them from each other. That is, the substrate to be processed first is shown as a substrate 100, and the substrate to be processed second is shown as a substrate 200. Note that since the basic configurations and operations of the laser irradiation apparatus 1 and the conveyance apparatus 600 are the same as those in the first embodiment, the descriptions thereof will be omitted as appropriate. For example, the operation for handing over a substrate among the conveyance units 11a to 11d and the rotation mechanism 68 is the same as that in the first embodiment.

As shown in FIG. 17, in a state in which the substrate 100 is in the first area 60a, a loading machine carries the substrate 200 into the fourth area 60d. Note that the substrate 100 is in an inclined state in which its edges are inclined from the x-axis. That is, similarly to the process shown in FIG. 10, the rotation mechanism 68 rotates the substrate 100, and then the conveyance unit 11a conveys the substrate 100 to the first area 60a.

Meanwhile, the substrate 200, which is in a parallel state, is carried into the fourth area 60d. In the state in which the edges of the substrate 200 are parallel to the x-axis, the substrate 200 is carried into the position over the main levitation unit 10. Then, as indicated by an outlined arrow in FIG. 17, the rotation mechanism 68 rotates the substrate 200 around the z-axis. When the rotation by the rotation mechanism 68 is finished, the substrate 200 changes from the parallel state to the inclined state. The substrate 200 is handed over from the rotation mechanism 68 to the conveyance unit 11a.

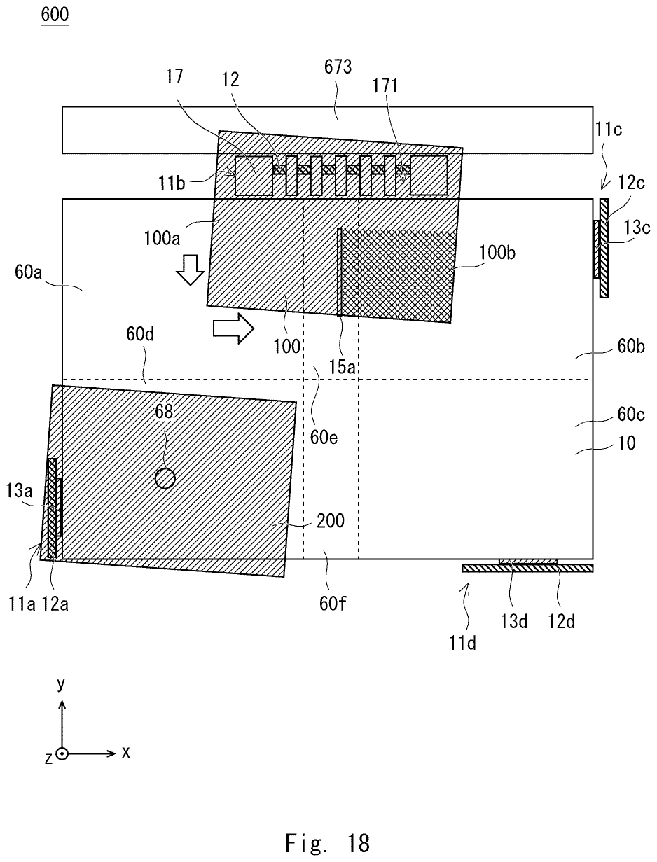

When the conveyance unit 11b conveys the substrate 100, it becomes a configuration shown in FIG. 18. In FIG. 18, the conveyance unit 11b is conveying the substrate 100 in a conveyance direction inclined from the x direction. Since the substrate 100 is passing through the irradiation area 15a of the laser light, the substrate 100 is irradiated with the line beam extending along the y direction. In this process, the conveyance direction and the direction of the edges of the substrate 100 are parallel to each other. A half of the substrate 100 on the −y side is irradiated with the laser light. Note that the edges of the substrate 200 and the edges of the substrate 100 are parallel to each other.

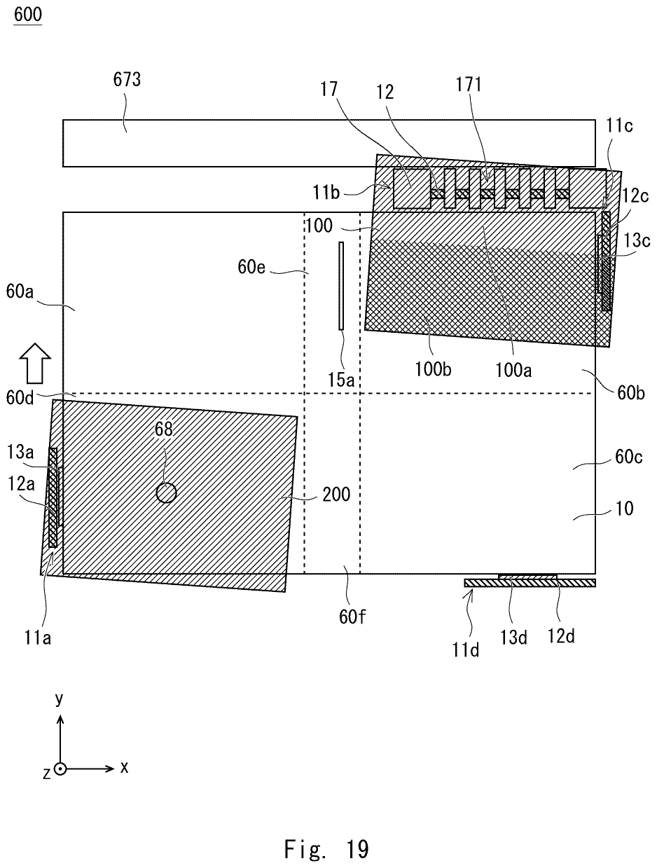

When the conveyance unit 11b further moves the substrate 100 in the conveyance direction, it becomes a configuration shown in FIG. 19. The substrate 100 passed through the irradiation area 15a and has already moved to the second area 60b. In the substrate 100, substantially a half of the area becomes an irradiated area 100b, and the remaining substantial half of the area becomes an unirradiated area 100a. The irradiated area 100b is the area on the −y side of the substrate 100, and the unirradiated area 100a is the area on the +y side of the substrate 100.

Further, after the conveyance unit 11b conveys the substrate 100, the conveyance unit 11a conveys the substrate 200 in the +y direction (indicated by an outlined arrow in FIG. 19). Note that the conveyance unit 11a may start conveying the substrate 200 while the conveyance unit 11b is conveying the substrate 100. The conveyance of the substrate 100 by the conveyance unit 11b and the conveyance of the substrate 200 by the conveyance unit 11a may be simultaneously performed or may be successively performed.

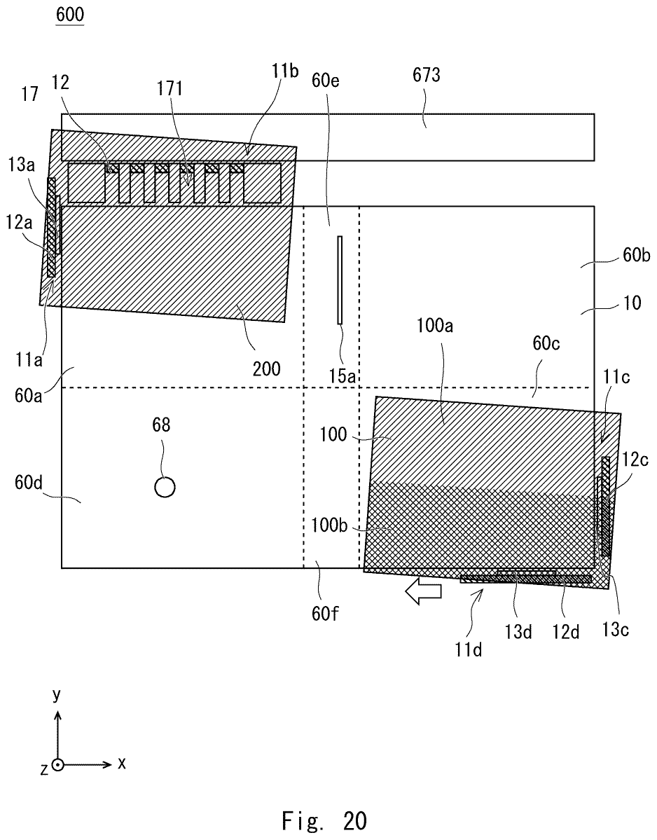

When the conveyance of the substrate 100 by the conveyance unit 11b is finished, the substrate 100 is handed over from the conveyance unit 11b to the conveyance unit 11c. The conveyance unit 11c moves the substrate 100 in the −y direction. When the conveyance of the substrate 100 by the conveyance unit 11c and the conveyance of the substrate 200 by the conveyance unit 11a are finished, it becomes a configuration shown in FIG. 20. The substrate 200 has been moved to the first area 60a, and the substrate 100 has been moved to the third area 60c.

The substrate 100 is handed over from the conveyance unit 11c to the conveyance unit 11d. Further, the substrate 200 is handed over from the conveyance unit 11a to the conveyance unit 11b. That is, after the conveyance unit 11b hands over the substrate 100 to the conveyance unit 11c, the conveyance unit 11b moves toward the −x side. As a result, the conveyance unit 11b returns from the second area 60b to the first area 60a. The moving direction of the conveyance unit 11b in this process is opposite to the conveyance direction of the substrate 100. Then, the holding mechanism 12 of the conveyance unit 11b sucks and holds the substrate 200, which is in the first area 60a.

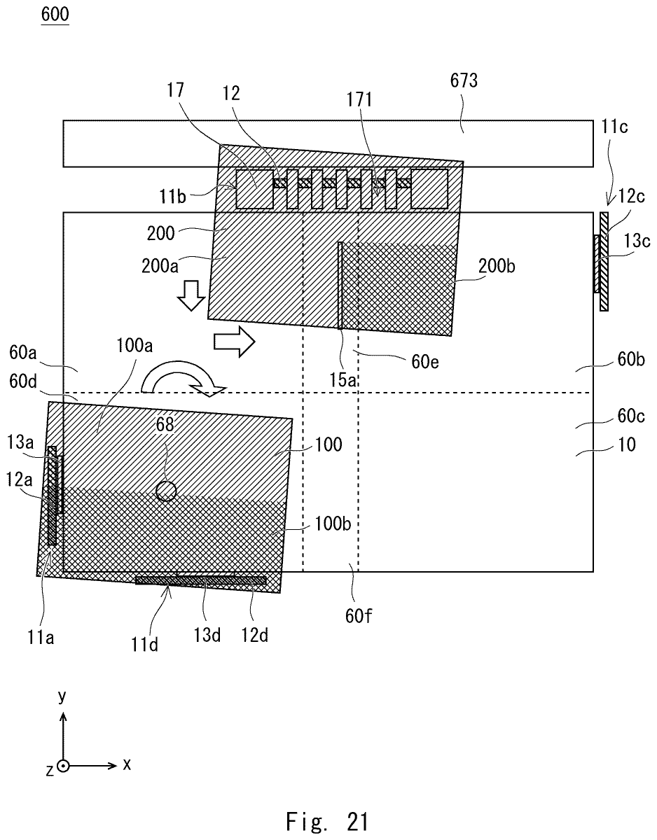

The conveyance unit 11b conveys the substrate 200 in the conveyance direction, and the conveyance unit 11d conveys the substrate 100 in the −x direction. When the conveyance by the conveyance unit 11d is finished, it becomes a configuration shown in FIG. 21. In FIG. 21, the substrate 200 has already passed through the irradiation area 15a by the conveyance by the conveyance unit 11b. Therefore, the half of the substrate 200 on the −y side becomes an irradiated area 200b. Note that the half of the substrate 200 on the +y side remains as the unirradiated area 200a. The conveyance direction by the conveyance unit 11b is inclined from the x direction. Specifically, the conveyance direction of the substrate 200 by the conveyance unit 11b is parallel to the edges of the substrate 200.

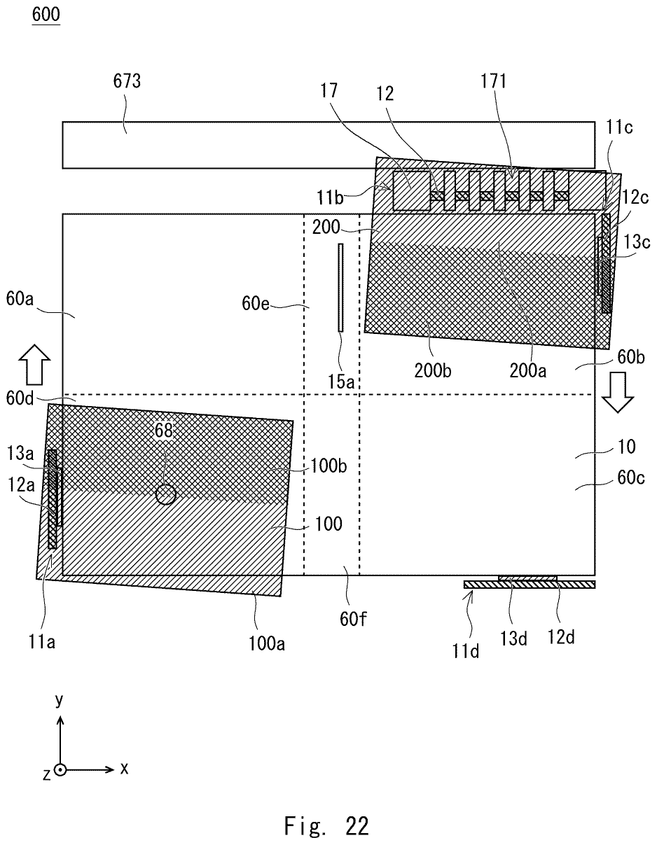

Then, when the conveyance by the conveyance unit 11d is finished, the substrate 100 is handed over from the conveyance unit 11d to the rotation mechanism 68. The rotation mechanism 68 rotates the substrate 100 by 180 degrees (indicated by an outlined arrow in FIG. 21). Further, as shown in FIG. 22, the conveyance unit 11c conveys the substrate 200 in the −y direction, and the conveyance unit 11a conveys the substrate 100 in the ty direction (indicated by an outlined arrow in FIG. 22). In FIG. 22, the half of the substrate 200 on the −y side becomes an irradiated area 200b, and the half of the substrate 100 on the −y side remains as the unirradiated area 100a.

The substrate 100 is conveyed in a circulating manner once again over the main levitation unit 10. Similarly, the substrate 200 is also conveyed in a circulating manner over the main levitation unit 10. Then, the rotation mechanism 68 rotates the substrate 200 by 180 degrees between the first and second rounds, i.e., after the first round and before the second round. The conveyance apparatus 600 conveys the substrates 100 and 200 in a circulating manner twice, so that the entire areas of the substrates 100 and 200 are irradiated with the laser light.

Further, each of the substrates 100 and 200 is taken out from the fourth area 60d when its second round of the conveyance is finished. Then, when the substrates 100 and 200 are taken out, the loading machine carries the next substrates into the fourth area 60d. By simultaneously conveying two substrates, the tact time can be shortened, so that the productivity can be improved.

### (Holding Position of Substrate)

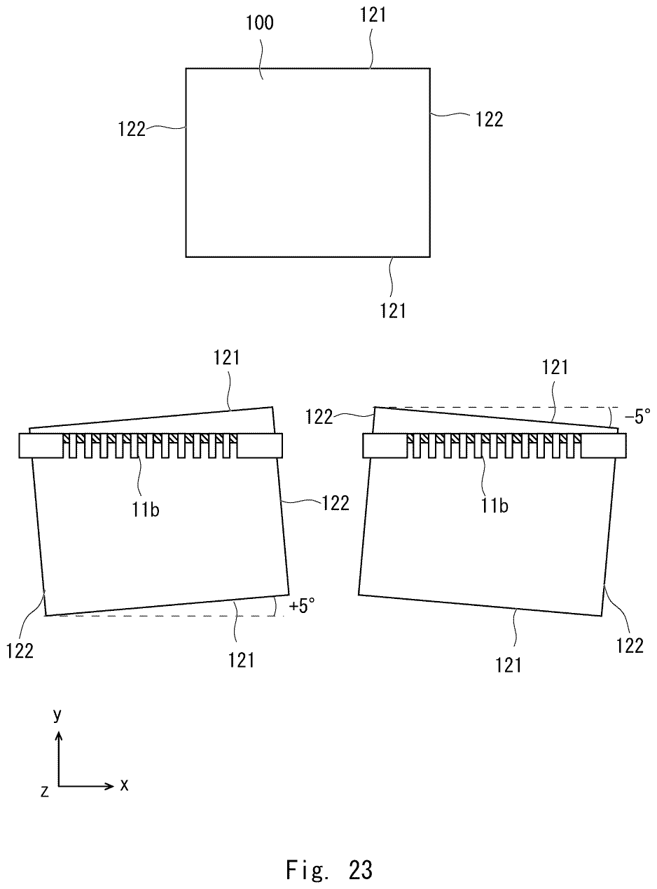

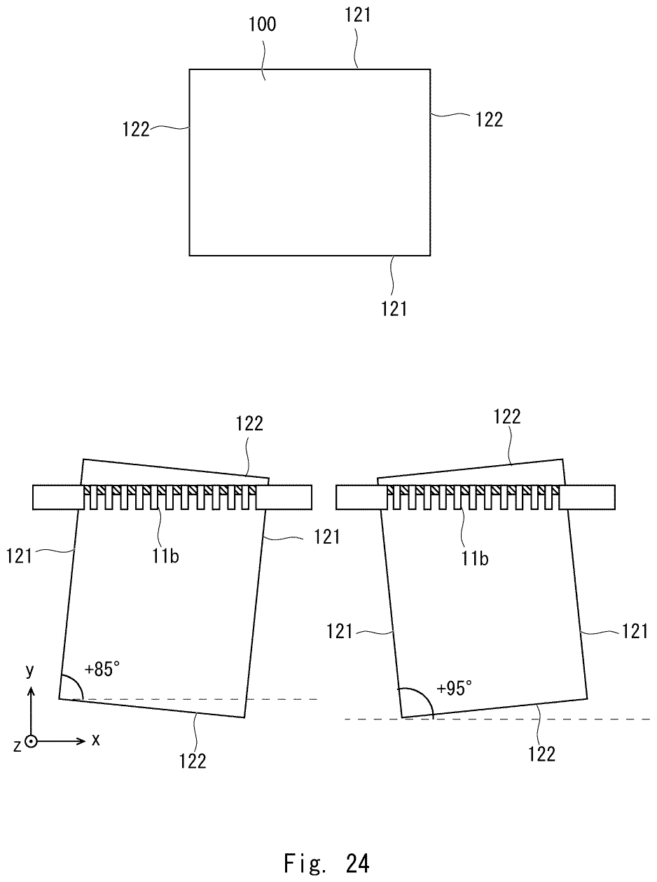

In the plan view, as shown in FIGS. 23 and 24, the substrate 100 has a rectangular shape having long sides 121 and short sides 122 shorter than the long sides 121. By controlling the rotation angle of the rotation mechanism 68, the conveyance unit 11b can hold the substrate 100 at the short side thereof. That is, the conveyance unit 11b can suck and hold the substrate 100 at or near its short side. This feature will be described with reference to FIGS. 23 and 24. FIG. 23 shows a state in which the conveyance unit 11b holds the long side 121 of the substrate 100. FIG. 24 shows a state in which the conveyance unit 11b holds the short side 122 of the substrate 100.

It is assumed that, for example, the loading machine carries the substrate 100 into the fourth area 60d in a parallel state in which the long sides 121 of the substrate 100 are parallel to the x direction. In this case, the rotation angle of the rotation mechanism 68 is in a range of −5° to 5°. Needless to say, the rotation angle is not limited to the aforementioned range. As shown in FIG. 23, the side of the substrate 100 on the +y side is the long side 121. Therefore, the conveyance unit 11b sucks and holds the long side 121 of the substrate 100. That is, the conveyance unit 11b is positioned directly below the long side 121 of the substrate 100 or the vicinity thereof. In this case, the short side 122 of the substrate 100 is disposed on the upstream side in the conveyance direction of the conveyance unit 11b.

In contrast, when the rotation angle of the rotation mechanism 68 is in a range of +85° to +95°, the side of the substrate 100 on the ty side is the short side 122 as shown in FIG. 24. Needless to say, the rotation angle is not limited to the aforementioned range. That is, φ may be −5° or smaller, or 5° or larger. Therefore, the conveyance unit 11b sucks and holds the short side 122 of the substrate 100. That is, the conveyance unit 11b is positioned directly below the short side of the substrate 100 or the vicinity thereof. In this case, the long side 121 of the substrate 100 is disposed on the upstream side in the conveyance direction of the conveyance unit 11b.

By controlling the rotation mechanism 68, it is possible to select whether the conveyance direction of the substrate 100 should be parallel to the short side of the substrate 100 or parallel to the long side thereof. That is, it is possible to select, depending on the laser irradiation process, whether the conveyance unit 11b conveys the substrate 100 along the short side 122 or along the long side 121. Needless to say, the conveyance direction of the substrate 100 may be parallel to neither the short side 122 nor the long side 121 of the substrate 100. The conveyance direction of the substrate 100 may be inclined from both the short side 122 and the long side 121 of the substrate 100. The substrate 100 can be conveyed at an angle suitable for the laser irradiation process. Therefore, a stable process can be performed, so that the productivity can be improved.

Further, as shown in FIG. 7, the wide movable levitation units 17A are disposed at both ends of the conveyance unit 11b in the y direction. Therefore, when the conveyance unit holds the long side 121 of the substrate 100, the short side 122 of the substrate 100 is positioned directly above the movable levitation unit 17A. It is possible to suppress the warping of the substrate 100 and prevent the substrate 100 from being damaged.

### Second Embodiment

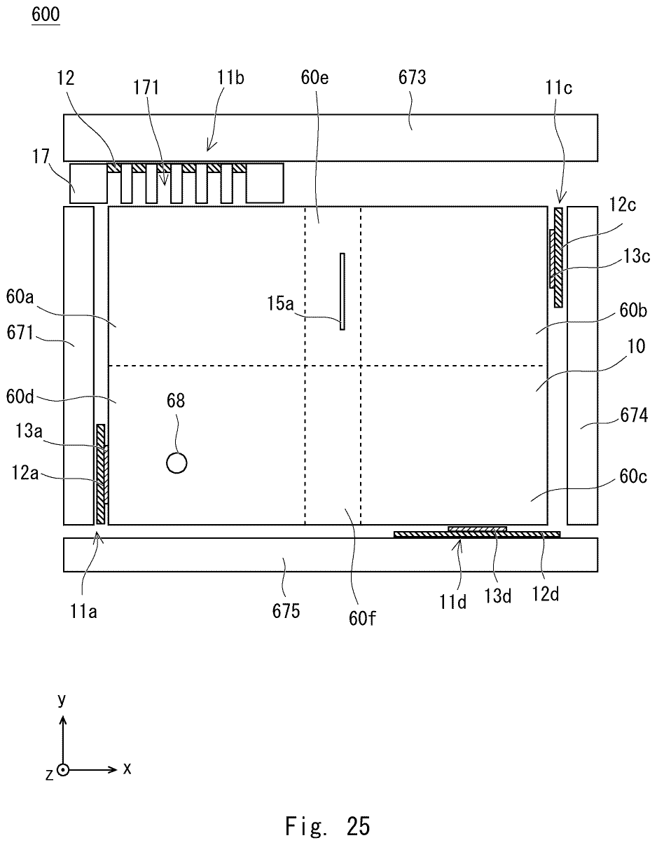

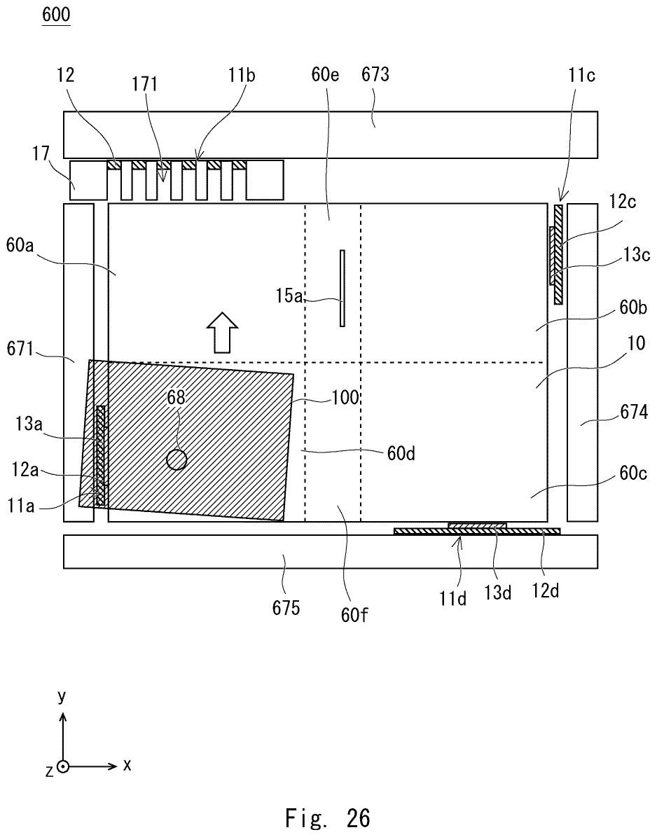

A conveyance apparatus 600 according to this embodiment will be described with reference to FIGS. 25 to 28. FIG. 25 is a plan view schematically showing the configuration of the conveyance apparatus 600. FIGS. 26 to 28 are plan views for explaining a conveyance operation in the second embodiment. The conveyance apparatus 600 includes end levitation units 671, 674 and 675. The components/structures other than the end levitation units 671, 674 and 675 are the same as those of the above-described embodiment, and therefore the descriptions thereof will be omitted. For example, the conveyance of the substrate 100 by the conveyance unit 11b is the same as that in the first embodiment, and therefore the description thereof will be omitted.

The conveyance apparatus 600 includes a main levitation unit 10 and end levitation units 671, 673, 674 and 675. The main levitation unit 10 levitates a substrate, which is the object to be processed, (not shown in FIG. 25). In the plan view, the main levitation unit 10 has a rectangular shape. The main levitation unit 10 includes two sides parallel to the y direction and two sides parallel to the x direction. The end levitation units 671, 673, 674 and 675 levitate an end of the substrate protruding beyond the main levitation unit 10.

The end levitation units 671, 673, 674 and 675 are disposed outside the main levitation unit 10. The end levitation units 671, 673, 674 and 675 are arranged along the outer periphery of the rectangular main levitation unit 10. The end levitation units 671, 673, 674 and 675 are arranged along the edges of the main levitation unit 10. In the plan view, the end levitation units 671, 673, 674 and 675 are arranged so as to surround the outer periphery of the main levitation unit 10.

The end levitation unit 671 is disposed on the −x side of the main levitation unit 10. The end levitation unit 673 is disposed on the ty side of the main levitation unit 10. The end levitation unit 674 is disposed on the +x side of the main levitation unit 10. The end levitation unit 675 is disposed on the −y side of the main levitation unit 10.

The end levitation unit 671 is disposed along the edge of the main levitation unit 10 on the −x side. That is, the end levitation unit 671 is disposed along the y direction. As shown in FIG. 26, the holding mechanism 12a holds a part of the substrate 100 located on the inner side of the part thereof located above the end levitation unit 671.

A conveyance unit 11a is provided between the main levitation unit 10 and the end levitation unit 671. The conveyance unit 11a is formed along the y direction. The conveyance unit 11a is disposed in such a manner that it can move in the gap between the main levitation unit 10 and the end levitation unit 671. As shown in FIG. 26, the conveyance unit 11a conveys the substrate 100 in the +y direction.

The conveyance unit 11a moves between the main levitation unit 10 and the end levitation unit 671. The conveyance unit 11a conveys the substrate 100 from the fourth area 60d toward the first area 60a (indicated by an outlined arrow in FIG. 26).

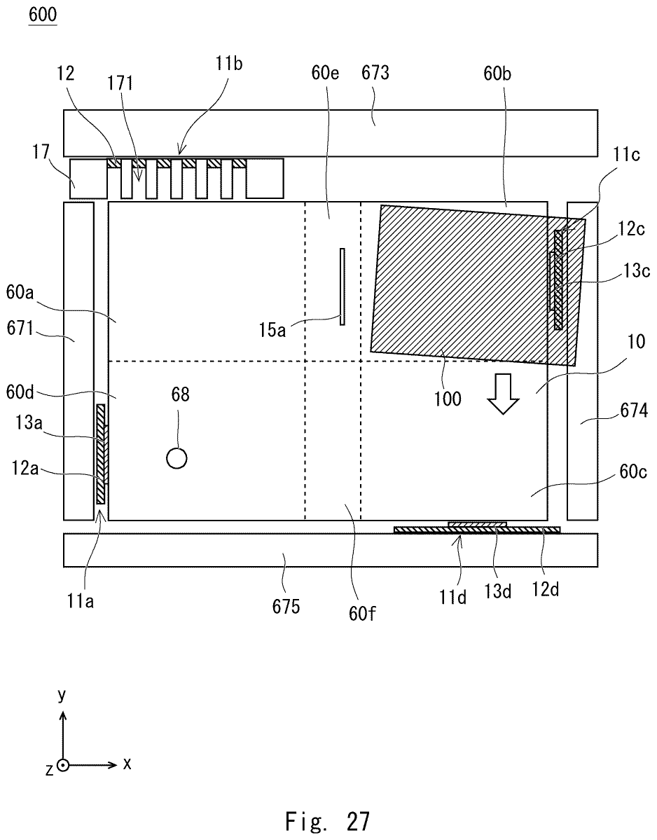

The end levitation unit 674 is disposed along the edge of the main levitation unit 10 on the +x side. That is, the end levitation unit 674 is disposed along the y direction. As shown in FIG. 27, the holding mechanism 12c holds a part of the substrate 100 located on the inner side of the part thereof located above the end levitation unit 674.

A conveyance unit 11c is provided between the main levitation unit 10 and the end levitation unit 674. The conveyance unit 11c is formed along the y direction. The conveyance unit 11c is disposed in such a manner that it can move in the gap between the main levitation unit 10 and the end levitation unit 674. As shown in FIG. 27, the conveyance unit 11c conveys the substrate 100 in the −y direction. The conveyance unit 11c moves between the main levitation unit 10 and the end levitation unit 674. The conveyance unit 11c conveys the substrate 100 from the second area 60b toward the third area 60c (indicated by an outlined arrow in FIG. 27).

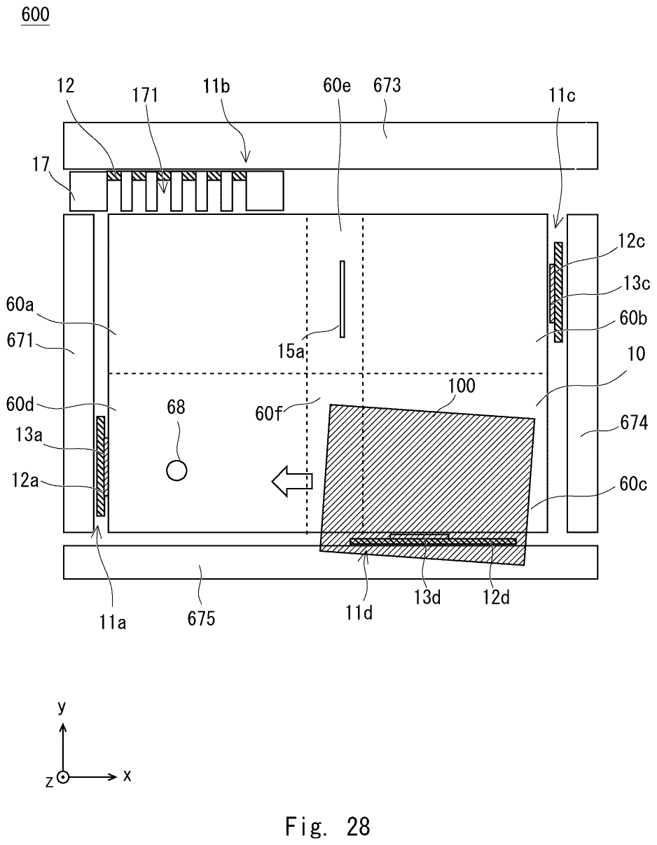

The end levitation unit 675 is disposed along the edge of the main levitation unit 10 on the −y side. That is, the end levitation unit 675 is disposed along the x direction. As shown in FIG. 28, the holding mechanism 12d holds a part of the substrate 100 located on the inner side of the part thereof located above the end levitation unit 675.

A conveyance unit 11d is provided between the main levitation unit 10 and the end levitation unit 675. The conveyance unit 11d is formed along the x direction. The conveyance unit 11d is disposed in such a manner that it can move in the gap between the main levitation unit 10 and the end levitation unit 675. As shown in FIG. 28, the conveyance unit 11d conveys the substrate 100 in the −x direction. The conveyance unit 11d moves between the main levitation unit 10 and the end levitation unit 675. The conveyance unit 11d conveys the substrate 100 from the third area 60c toward the fourth area 60d (indicated by an outlined arrow in FIG. 28).

As described above, by providing the end levitation units 671, 673, 674 and 675 around the main levitation unit 10, it is possible to eject gas onto the ends of the substrate 100. In this way, the warping of the ends of the substrate 100 can be suppressed.

In particular, the conveyance apparatus 600 conveys the substrate 100 in a circulating manner in the state in which the edges of the substrate 100 are inclined from the x and y directions. In the plan view, the holding mechanisms 12a, 12c, and 12d suck and hold the substrate 100 in the state in which the long-side direction of the conveyance units 11a, 11c and 11d is not parallel to the edge of the substrate 100. Therefore, the substrate 100 is conveyed in the state in which the edge of the substrate 100 and its vicinity protrude outward from the conveyance units 11a, 11c and 11d.

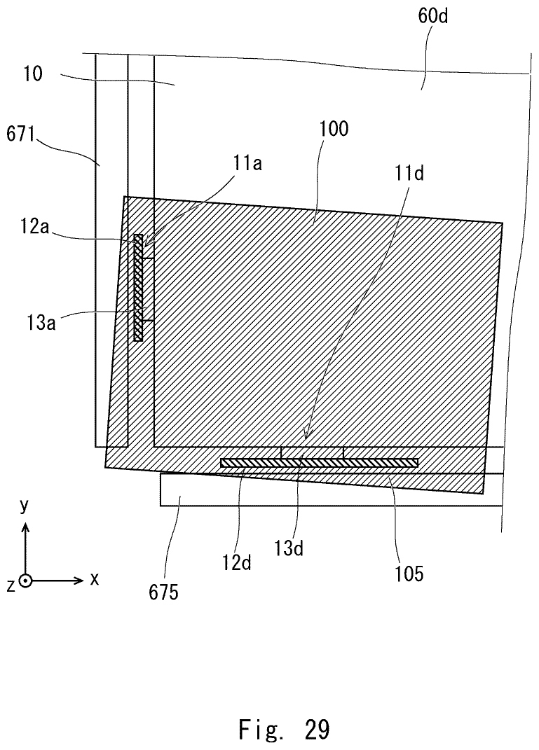

As described in the first embodiment, the rotation mechanism 68 rotates the substrate 100 so that the edges of the substrate 100 are inclined from the x and y directions. As shown in FIG. 29, the substrate 100 in the inclined state has a protruding part 105 protruding beyond the conveyance unit 11d toward the −y side. The end levitation unit 675 ejects gas onto the protruding part 105. Therefore, it is possible to suppress the warping of the protruding part 105 of the substrate 100, and thereby to prevent the substrate 100 from colliding with other structures. In this way, it is possible to prevent the substrate 100 from being damaged, and thereby to improve the productivity.

Note that the conveyance unit 11b includes the movable levitation unit 17 as shown in FIGS. 1 to 3. When the substrate 100 is moved from the fourth area 60d to the first area 60a, the end of the substrate 100 on the ty side passes through the gap between the main levitation unit 10 and the end levitation unit 673. During this process, the movable levitation unit 17 ejects gas onto the substrate 100. In this way, it is possible to prevent the substrate 100 from bending and colliding with the edge of the main levitation unit 10 or the end levitation unit 673, or a structure therearound. As described above, the gap between the end levitation unit 673 and the main levitation unit 10 is wider than the gap between any of the other end levitation units and the main levitation unit 10. Even in such a case, it is possible to prevent the substrate 100 from bending by providing the movable levitation unit 17 in the conveyance unit 11b. Similarly to Modified Example 1, two substrates 100 may be simultaneously conveyed in the second embodiment.

Note that although the end levitation units 671, 673, 674 and 675 are rectangular in the plan view, the planar shapes of the end levitation units 671, 673, 674 and 675 are not limited to rectangular shapes. For example, the widths of the end levitation units 671, 673, 674 and 675 may be partially increased. When the rotation mechanism 68 rotates the substrate, the length of the protrusion of the substrate 100 increases during the rotation. Therefore, the widths of only the parts of the end levitation units 671 and 675 where the rotation mechanism 68 rotates the substrate 100 may be increased.

Specifically, the width of the part of the end levitation unit 671 on the −y side is increased, and the width of the part of the end levitation unit 675 on the −X side is increased. That is, the widths of only the parts of the end levitation units 671 and 675 located near the fourth area 60d are increased.

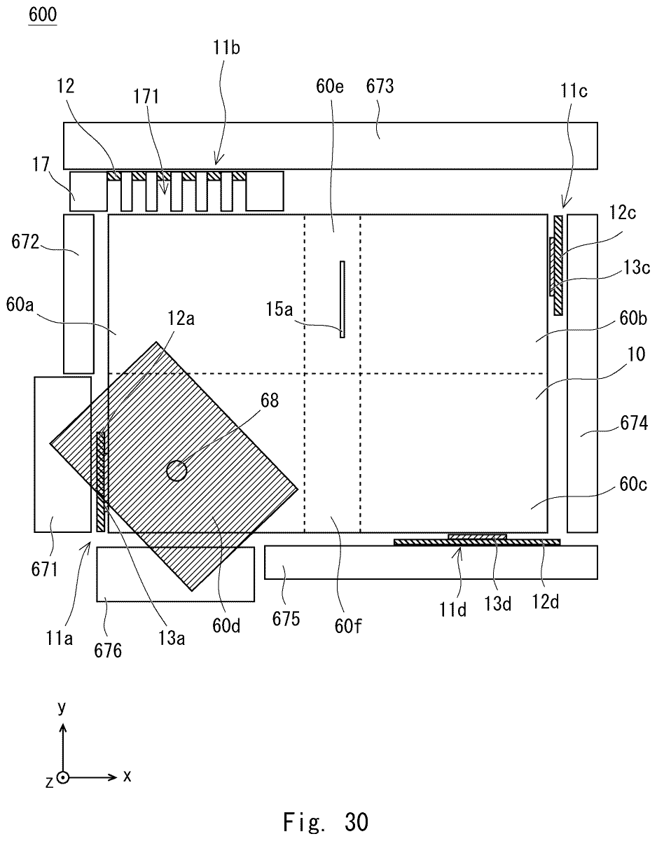

Note that in the case where the width of the rotating part of the substrate is increased, a wide end levitation unit 671 and a narrow end levitation unit 672 may be provided on the −x side of the main levitation unit 10 as shown in FIG. 30. Similarly, a narrow end levitation unit 675 and a wide end levitation unit 676 may be provided on the −y side of the main levitation unit 10.

### Third Embodiment

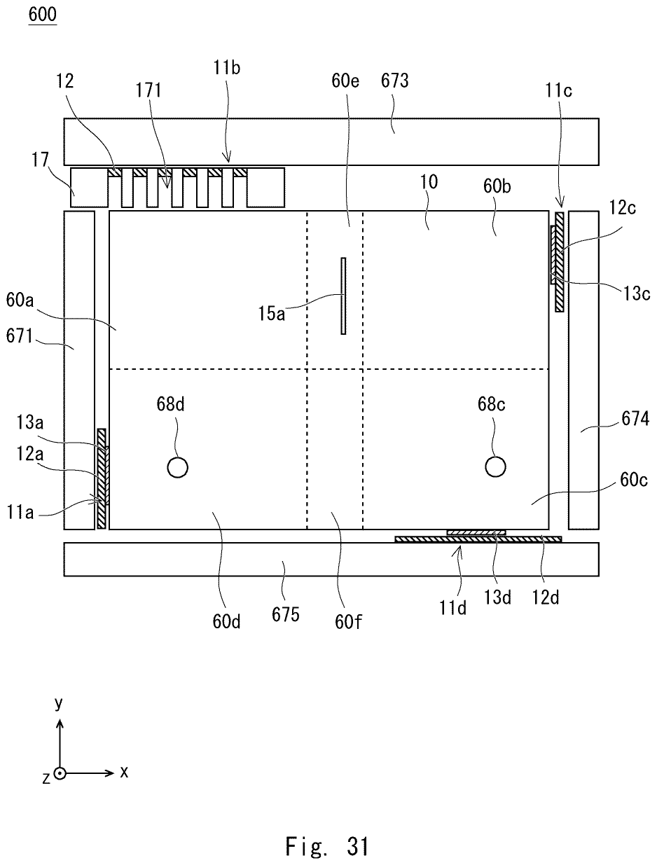

A configuration of a conveyance apparatus 600 according to this embodiment will be described with reference to FIG. 31. In the third embodiment, a rotation mechanism 68c is provided in the third area 60c. In this embodiment, as shown in FIG. 31 and the like, the rotation mechanism of the fourth area 60d is referred to as a rotation mechanism 68d, and the rotation mechanism of the third area 60c is referred to as a rotation mechanism 68c to distinguish them from each other. The components/structures other than the rotation mechanism 68c are the same as those of the first and second embodiments, and therefore the descriptions thereof will be omitted.

The rotation axis of the rotation mechanism 68c is parallel to the z-axis. The rotation mechanism 68c rotates the substrate 100. Similarly to the rotation mechanism 68d, the rotation mechanism 68c includes a sucking and holding mechanism, a rotary motor, a lifting/lowering mechanism, and the like. Further, the rotation mechanism 68c rotates the substrate 100 which has already been irradiated with the laser light. As a result, the edges of the substrate 100 become parallel to the x or y direction.

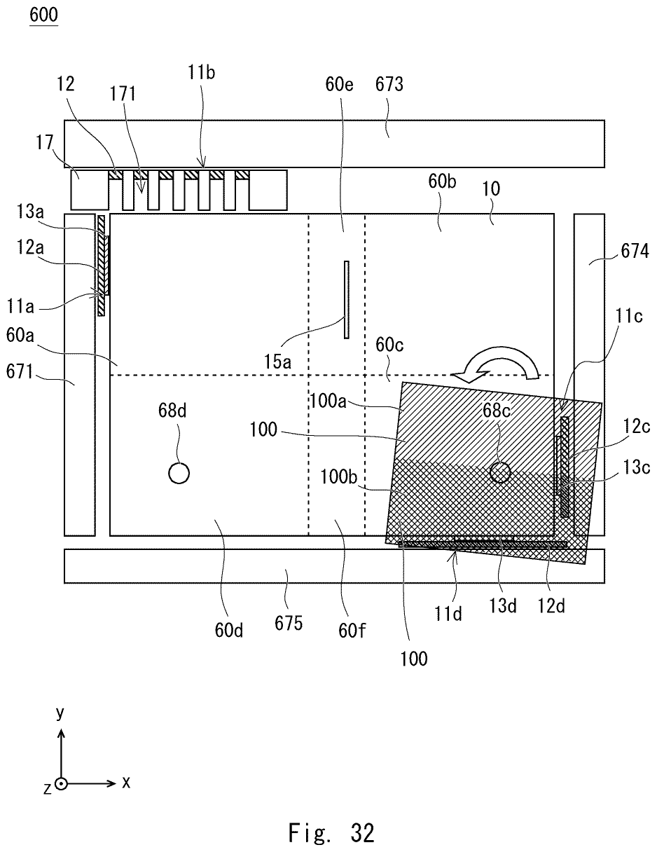

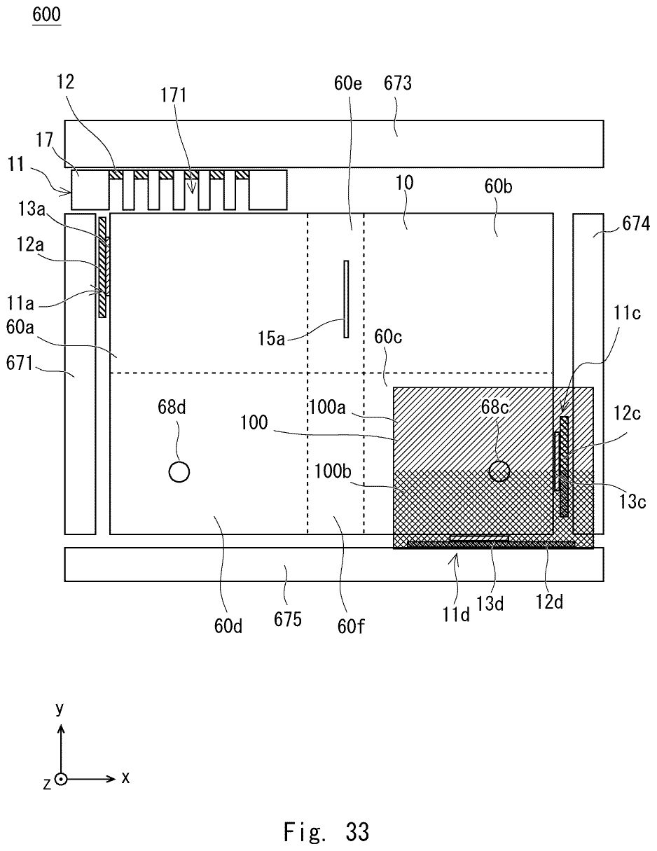

A conveyance operation performed by the conveyance apparatus 600 will be described with reference to FIGS. 32 and 33. FIG. 32 is a plan view showing a state in which the substrate 100 has just been conveyed to the third area 60c. Specifically, the state shown in FIG. 32 corresponds to the state shown in FIG. 14. Therefore, substantially a half of the substrate 100 has become an irradiated area 100b.

Then, as indicated by an outlined arrow in FIG. 32, the rotation mechanism 68c rotates the substrate 100. As a result, as shown in FIG. 33, the long sides of the substrate 100 become parallel to the x direction. That is, the state of the substrate 100 changes from the inclined state to the parallel state. Then, the conveyance unit 11d holds the substrate 100 in the parallel state and conveys it in the −x direction. In this way, the conveyance unit 11d can reliably hold the substrate 100. This feature will be described hereinafter.

For example, when the conveyance unit 11d holds the substrate 100 in the inclined state, it causes a protruding part 105 where the substrate 100 protrudes from the conveyance unit 11d (see FIG. 29). If the conveyance position by the conveyance unit 11c deviates in the −y direction, the protruding part 105 becomes small. In this case, the substrate 100 cannot completely cover the holding mechanism 12d of the conveyance unit 11d, so that the sucking and holding by the conveyance unit 11d may be disengaged. By providing the rotation mechanism 68d as being provided in this embodiment, the conveyance unit 11d can convey the substrate 100 in the parallel state.

Further, after the conveyance unit 11d moves the substrate 100 from the third area 60c to the fourth area 60d, the rotation mechanism 68d rotates the substrate 100 again. As a result, the substrate 100 becomes the inclined state. Then, the conveyance units 11a, 11b and 11c successively convey the substrate 100 in the inclined state.

A conveyance method according to this embodiment includes: (A1) a step of rotating, by the first rotation mechanism, the substrate over the main levitation unit so that an angle of the edge of the substrate with respect to a line direction of the laser light becomes a first angle; (A2) a step of conveying, by the first conveyance mechanism, the substrate rotated by the first rotation mechanism in a first direction in a state in which the angle of the edge of the substrate is the first angle; and (A3) a step of conveying, by the second conveyance mechanism, in order to change an irradiation place of the laser light on the substrate, the substrate conveyed by the first conveyance mechanism in a second direction in a state in which the angle of the edge of the substrate is the first angle.

### (Organic EL Display)

A semiconductor device having the above-described polysilicon film is suitable for a TFT (Thin Film transistor) array substrate for an organic EL (Electro Luminescence) display. That is, the polysilicon film is used as a semiconductor layer including source regions, channel regions, and drain regions of TFTs.

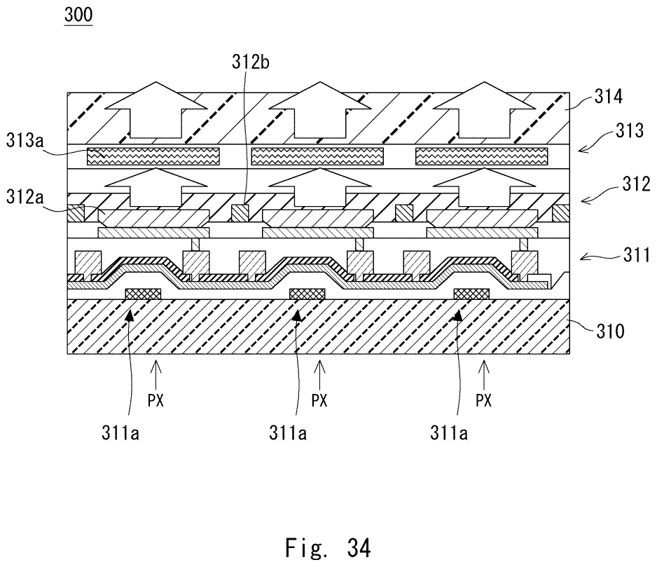

A configuration in which a semiconductor device according to this embodiment is applied to an organic EL display will be described hereinafter. FIG. 34 is a simplified cross-sectional view of pixel circuits of an organic EL display device. The organic EL display 300 shown in FIG. 34 is an active matrix-type display device in which a TFT(s) is disposed in each pixel PX.

The organic EL display device 300 includes a substrate 310, a TFT layer 311, an organic layer 312, a color filter layer 313, and a sealing substrate 314. FIG. 34 shows a top-emission-type organic EL display device, in which the side of the sealing substrate 314 is located on the viewing side. Note that the following description is given to show an example of a configuration of an organic EL display device and this embodiment is not limited to the below-described configuration. For example, a semiconductor device according to this embodiment may be used for a bottom-emission-type organic EL display device.

The substrate 310 is a glass substrate or a metal substrate. The TFT layer 311 is provided over the substrate 310. The TFT layer 311 includes TFTs 311a disposed in the respective pixels PX. Further, the TFT layer 311 includes wiring lines (not shown) or the like connected to the TFTs 311a. The TFTs 311a, the wirings, and the like constitute pixel circuits.

The organic layer 312 is provided over the TFT layer 311. The organic layer 312 includes an organic EL light-emitting element 312a disposed in each pixel PX. Further, in the organic layer 312, separation walls 312b for separating organic EL light-emitting elements 312a are provided between pixels PX.

The color filter layer 313 is provided over the organic layer 312. The color filter layer 313 includes color filters 313a for performing color displaying. That is, in each pixel PX, a resin layer colored in R (red), G (green), or B (blue) is provided as the color filter 313a.

The sealing substrate 314 is provided over the color filter layer 313. The sealing substrate 314 is a transparent substrate such as a glass substrate and is provided to prevent deterioration of the organic EL light-emitting elements of the organic layer 312.

Electric currents flowing through the organic EL light-emitting elements 312a of the organic layer 312 are changed by display signals supplied to the pixel circuits. Therefore, it is possible to control an amount of light emitted in each pixel PX by supplying a display signal corresponding to a display image to each pixel PX. As a result, it is possible to display a desired image.

In an active matrix-type display device such as an organic EL display, at least one TFT (e.g., a switching TFT or a driving TFT) is provided in one pixel PX. Further, a semiconductor layer including a source region, a channel region, and a drain region is provided in the TFT in each pixel PX. A polysilicon film according to this embodiment is suitable for a semiconductor layer of TFTs. That is, by using a polysilicon film manufactured by the above-described manufacturing method for a semiconductor layer of a TFT array substrate, it is possible to prevent or reduce in-plane variations of TFT characteristics. Therefore, it is possible to manufacture display devices having excellent display characteristics with high productivity.

### (Method for Manufacturing Semiconductor Device)

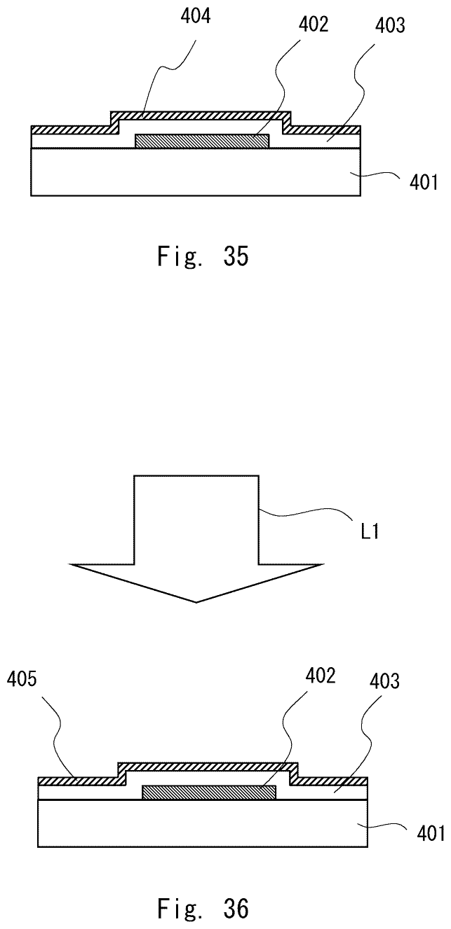

The method for manufacturing a semiconductor device by using a laser irradiation apparatus according to this embodiment is suitable for manufacturing of a TFT array substrate. A method for manufacturing a semiconductor device including a TFT will be described with reference to FIGS. 35 and 35. Each of FIGS. 35 and 36 is a cross-sectional view showing a step in a method for manufacturing a semiconductor device. In the following description, a method for manufacturing a semiconductor device including an inverted staggered-type TFT will be described. Each of FIGS. 35 and 36 shows one of the steps for forming a polysilicon film in a method for manufacturing a semiconductor. Note that other manufacturing steps can be performed by using known techniques, and therefore descriptions thereof are omitted as appropriate.

As shown in FIG. 35, a gate electrode 402 is formed over a glass substrate 401. A gate insulating film 403 is formed over the gate electrode 402. An amorphous silicon film 404 is formed over the gate insulating film 403. The amorphous silicon film 404 is disposed so as to be placed over the gate electrode 402 with the gate insulating film 403 interposed therebetween. For example, the gate insulating film 403 and the amorphous silicon film 404 are successively formed by a CVD (Chemical Vapor Deposition) method.

Then, the glass substrate 401, over which the amorphous silicon film 404 has been formed, is conveyed to the above-described conveyance apparatus 600. Then, by irradiating the amorphous silicon film 404 with laser light L1, a polysilicon film 405 is formed as shown in FIG. 36. That is, the amorphous silicon film 404 is crystallized by the laser irradiation apparatus 1 shown in FIG. 1 or the like. As a result, a polysilicon film 405 that is formed as silicon is crystallized is formed over the gate insulating film 403. The polysilicon film 405 corresponds to the above-described polysilicon film. The glass substrate 401 is irradiated with the laser light L1 while the conveyance apparatus 600 is conveying the glass substrate 401. As a result, the amorphous silicon film 404 is annealed and converted into a polysilicon film 405.

A method for manufacturing a semiconductor device according to this embodiment includes: (sa1) forming an amorphous film over a substrate; (sa2) loading the substrate with the amorphous film formed thereover onto a conveyance apparatus 600; and (sa3) irradiating the substrate with line-shaped laser light while conveying the substrate using the conveyance apparatus 600, and thereby annealing the amorphous film so that the amorphous film is crystallized into a crystallized film.

Further, the above descriptions are given on the assumption that a laser annealing apparatus according to this embodiment is one in which a polysilicon film is formed by applying laser light to an amorphous silicon film. However, the present disclosure may be applied to other cases in which a micro-crystalline film is formed by applying laser light to an amorphous silicon film. Further, the laser light used for the annealing is not limited to Nd: YAG laser. Further, a method according to this embodiment can also be applied to a laser annealing apparatus for crystallizing a thin film other than the silicon film. That is, the method according to this embodiment can be applied to any laser annealing apparatus in which a crystallized film is formed by applying laser light to an amorphous film. According to the laser annealing apparatus in accordance with this embodiment, it is possible to appropriately reform (or modify) a substrate including a crystallized film.

The first to third embodiments and its modified examples can be combined with one another as appropriate. For example, end levitation units 671, 674 and 675, and the like may be provided in a conveyance apparatus 600 that simultaneously conveys a plurality of substrates.

Note that the present invention is not limited to the above-described embodiments, and they can be modified as appropriate without departing from the scope and spirit of the invention.

### REFERENCE SIGNS LIST

1 LASER IRRADIATION APPARATUS
10 MAIN FLOATATION UNIT
11 CONVEYANCE UNIT
12 HOLDING MECHANISM
14 LASER IRRADIATION UNIT
15 LASER BEAM
15a IRRADIATED AREA
17 MOVABLE FLOATATION UNIT
18 END FLOATATION UNIT
31 PRECISION FLOATATION AREA
33 ROUGH FLOATATION AREA
60a FIRST AREA
60b SECOND AREA
60c THIRD AREA
60d FOURTH AREA
60e PROCESS AREA
60f PASSAGE AREA
671-676 END FLOATATION UNIT
68 ROTATION MECHANISM
100 SUBSTRATE
100a UNIRRADIATED AREA
100b IRRADIATED AREA
111 PRECISION FLOATATION UNIT
113 ROUGH FLOATATION UNIT
131 FLOATATION UNIT CELL
220 x-MOVING MECHANISM
230 y-MOVING MECHANISM
240 LIFTING/LOWERING MECHANISM
300 ORGANIC EL DISPLAY
310 SUBSTRATE
311 TFT LAYER
311a TFT
312 ORGANIC LAYER
312a ORGANIC EL LIGHT-EMITTING ELEMENT
312b SEPARATION WALL
313 COLOR FILTER LAYER
313a COLOR FILTER (CF)
314 SEALING SUBSTRATE
401 GLASS SUBSTRATE
402 GATE ELECTRODE
403 GATE INSULATING FILM
404 AMORPHOUS SILICON FILM
405 POLYSILICON FILM
671-676 END FLOATATION UNIT
PX PIXEL

1. A conveyance apparatus configured to convey a substrate in order to irradiate the substrate with line-shaped laser light, and comprising:
a main levitation unit configured to levitate the substrate over a top surface thereof;
a first rotation mechanism configured to rotate the substrate over the main levitation unit so that an angle of an edge of the substrate with respect to a line direction of the laser light becomes a first angle in a plan view;
a first conveyance mechanism configured to convey the substrate rotated by the first rotation mechanism in a first direction in a state in which the angle of the edge of the substrate is the first angle; and
a second conveyance mechanism configured to convey, in order to change an irradiation place of the laser light on the substrate, the substrate conveyed by the first conveyance mechanism in a second direction in the state in which the angle of the edge of the substrate is the first angle.

2. The conveyance apparatus according to claim 1, wherein
in the plan view, the first direction is a direction inclined from the edge of the substrate the angle of which is the first angle, and
in the plan view, the second direction is a direction parallel to the edge of the substrate the angle of which is the first angle.

3. The conveyance apparatus according to claim 2, wherein the second conveyance mechanism comprises:
a plurality of holding mechanisms configured to suck and hold the substrate;
a plurality of movable levitation units configured to eject gas onto the substrate;
a first moving mechanism configured to move the plurality of holding mechanisms in the first direction; and
a second moving mechanism configured to move the plurality of holding mechanisms, the plurality of movable levitation units, and the first moving mechanism in an orthogonal direction orthogonal to the first direction,
the plurality of movable levitation units are arranged in the orthogonal direction with a space therebetween, and
the holding mechanism moves the space between two movable levitation units in the first direction.

4. The conveyance apparatus according to claim 3, further comprising:
a third conveyance mechanism configured to convey the substrate conveyed by the second conveyance mechanism in a third direction opposite to the first direction; and
a fourth conveyance mechanism configured to convey the substrate conveyed by the third conveyance mechanism in a fourth direction.

5. The conveyance apparatus according to claim 4, wherein the fourth direction is a direction inclined from the second direction.

6. The conveyance apparatus according to claim 3, further comprising an end levitation unit provided outside the main levitation unit and configured to eject gas onto an end of the substrate, wherein
the second conveyance mechanism moves between the main levitation unit and the end levitation unit.

7. The conveyance apparatus according to claim 1, wherein the main levitation unit levitates a plurality of substrates.

8. The conveyance apparatus according to claim 1, further comprising a second rotation mechanism configured to rotate the substrate conveyed by the second conveyance mechanism so that the edge of the substrate becomes parallel to the first direction.

9. A conveyance method for conveying a substrate by using a conveyance apparatus in order to irradiate the substrate with line-shaped laser light, wherein
the conveyance apparatus comprises:
a main levitation unit including an irradiation area disposed directly below an irradiation place of the laser light, and configured to levitate the substrate over a top surface thereof;
a first rotation mechanism configured to rotate the substrate over the main levitation unit in a plan view;
a first conveyance mechanism configured to convey the substrate in a first direction over the main levitation unit; and
a second conveyance mechanism configured to convey the substrate in a second direction over the main levitation unit, and
the conveyance method comprises the steps of:
(A1) rotating, by the first rotation mechanism, the substrate over the main levitation unit so that an angle of the edge of the substrate with respect to a line direction of the laser light becomes a first angle;
(A2) conveying, by the first conveyance mechanism, the substrate rotated by the first rotation mechanism in a first direction in a state in which the angle of the edge of the substrate is the first angle; and
(A3) conveying, by the second conveyance mechanism, in order to change an irradiation place of the laser light on the substrate, the substrate conveyed by the first conveyance mechanism in a second direction in a state in which the angle of the edge of the substrate is the first angle.

10. The conveyance method according to claim 9, wherein
in the plan view, the first direction is a direction inclined from the edge of the substrate the angle of which is the first angle, and
in the plan view, the second direction is a direction parallel to the edge of the substrate the angle of which is the first angle.

11. The conveyance method according to claim 10, wherein
the second conveyance mechanism comprises:
a plurality of holding mechanisms configured to suck and hold the substrate;
a plurality of movable levitation units configured to eject gas onto the substrate;
a first moving mechanism configured to move the plurality of holding mechanisms in the first direction; and
a second moving mechanism configured to move the plurality of holding mechanisms, the plurality of movable levitation units, and the first moving mechanism in an orthogonal direction orthogonal to the first direction,
the plurality of movable levitation units are arranged in the orthogonal direction with a space therebetween, and
the holding mechanism moves the space between two movable levitation units in the first direction.

12. The conveyance method according to claim 11, wherein
the conveyance apparatus further comprises:
a third conveyance mechanism configured to convey the substrate conveyed by the second conveyance mechanism in a third direction opposite to the first direction; and
a fourth conveyance mechanism configured to convey the substrate conveyed by the third conveyance mechanism in a fourth direction.

13. The conveyance method according to claim 12, wherein the fourth direction is a direction inclined from the second direction.

14. The conveyance method according to claim 13, wherein
the conveyance apparatus further comprises:
an end levitation unit provided outside the main levitation unit and configured to eject gas onto an end of the substrate, and
the second conveyance mechanism moves between the main levitation unit and the end levitation unit.

15. The conveyance method according to claim 9, wherein the main levitation unit levitates a plurality of substrates.

16. The conveyance method according to claim 9, wherein the conveyance apparatus further comprises a second rotation mechanism configured to rotate the substrate conveyed by the second conveyance mechanism so that the edge of the substrate becomes parallel to the first direction.

17. A method for manufacturing a semiconductor device, comprising the steps of:
(sa1) forming an amorphous film over a substrate;
(sa2) loading the substrate with the amorphous film formed thereover onto a conveyance apparatus; and
(sa3) irradiating the substrate with line-shaped laser light while conveying the substrate using the conveyance apparatus, and thereby annealing the amorphous film so that the amorphous film is crystallized into a crystallized film,
the conveyance apparatus comprising:
a main levitation unit including an irradiation area disposed directly below an irradiation place of the laser light, and configured to levitate the substrate over a top surface thereof;
a first rotation mechanism configured to rotate the substrate over the main levitation unit so that an angle of the edge of the substrate with respect to a line direction of the laser light becomes a first angle in a plan view;
a first conveyance mechanism configured to convey the substrate rotated by the first rotation mechanism in a first direction in a state in which the angle of the edge of the substrate is the first angle; and
a second conveyance mechanism configured to convey, in order to change an irradiation place of the laser light on the substrate, the substrate conveyed by the first conveyance mechanism in a second direction in the state in which the angle of the edge of the substrate is the first angle.

18. The method for manufacturing a semiconductor device according to claim 17, wherein
in the plan view, the first direction is a direction inclined from the edge of the substrate the angle of which is the first angle, and
in the plan view, the second direction is a direction parallel to the edge of the substrate the angle of which is the first angle.

19. The method for manufacturing a semiconductor device according to claim 18, wherein
the second conveyance mechanism comprises:
a plurality of holding mechanisms configured to suck and hold the substrate;
a plurality of movable levitation units configured to eject gas onto the substrate;
a first moving mechanism configured to move the plurality of holding mechanisms in the first direction; and
a second moving mechanism configured to move the plurality of holding mechanisms, the plurality of movable levitation units, and the first moving mechanism in an orthogonal direction orthogonal to the first direction,
the plurality of movable levitation units are arranged in the orthogonal direction with a space therebetween, and
the holding mechanism moves the space between two movable levitation units in the first direction.

20-24. (canceled)

25. A laser irradiation apparatus comprises:
a conveyance apparatus according to claim 1; and
a laser irradiation unit configured to irradiating the substrate with line-shaped laser light;
